(19) United States
(12) Patent Application Publication
(10) Pub. No.: US 2026/0305056 A1
(43) Pub. Date: Oct. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: Hae Ju YUN, Yongin-si (KR); Soo Bin KIM, Yongin-si (KR); Yong Seok KIM, Yongin-si (KR); Ji Young NAM, Yongin-si (KR); Dong Chul SHIN, Yongin-si (KR); Jong Cheon LEE, Yongin-si (KR)

(21) Appl. No.: 19/424,997

(22) Filed: Dec. 18, 2025

(30) Foreign Application Priority Data
Mar. 27, 2025 (KR) 10-2025-0039276

(51) Int. Cl. H10K 39/34; G06F 3/041; H10K 59/122; H10K 59/40; H10K 59/80

(52) U.S. Cl. CPC H10K 39/34; H10K 59/122; H10K 59/40; H10K 59/873; H10K 59/879; G06F 3/0412

(57) ABSTRACT

A display device and an electronic device including the same are provided. The display device includes a substrate; a plurality of light-emitting pixel electrodes on one side of the substrate; a plurality of sensing pixel electrodes on one surface of the substrate and spaced from the plurality of light-emitting pixel electrodes; a pixel defining layer exposing a portion of each of the plurality of light-emitting pixel electrodes and the plurality of sensing pixel electrodes and defining a plurality of light-emitting areas and a plurality of photo-sensing areas; a plurality of light-emitting layers on the plurality of light-emitting pixel electrodes in the plurality of light-emitting areas; a plurality of photo-sensing layers on the plurality of sensing pixel electrodes in the plurality of photo-sensing areas; a common electrode on the pixel defining layer, the plurality of light-emitting layers, and the plurality of photo-sensing layers.

### CROSS-REFERENCE TO RELATED APPLICATION

This application claims priority to and the benefit of Korean Patent Application No. 10-2025-0039276, filed on Mar. 27, 2025, in the Korean Intellectual Property Office, the entire disclosure of which is incorporated by reference herein.

### BACKGROUND

### 1. Field

The present disclosure relates to a display device and an electronic device including the same.

### 2. Description of the Related Art

With the advancement of the information society, various types of display devices have been developed to display information. The display device may provide a specific image to a user by using light-emitting elements, or may collect biometric information such as fingerprints and blood pressure from the user by using photo-sensing elements.

When providing an image to the user, it is important to increase light emission efficiency by increasing the amount of light emitted from the light-emitting elements to the outside of the display device. In addition, in order to increase the accuracy in collection of biometric information, it is important to increase the amount of light incident on the photo-sensing elements. To this end, various methods of modifying light paths by arranging optical members in the display device are studied.

### SUMMARY

Aspects and features of embodiment of the present disclosure provide a display device that increases the amount of light incident on photo-sensing elements, and an electronic device including the same.

Aspects and features of embodiment of the present disclosure provide a display device that increases the amount of light emitted from light-emitting areas, and an electronic device including the same.

According to one or more embodiments of the present disclosure, a display device includes a substrate; a plurality of light-emitting pixel electrodes on one side of the substrate; a plurality of sensing pixel electrodes on one surface of the substrate and spaced from the plurality of light-emitting pixel electrodes; a pixel defining layer exposing a portion of each of the plurality of light-emitting pixel electrodes and the plurality of sensing pixel electrodes and defining a plurality of light-emitting areas and a plurality of photo-sensing areas; a plurality of light-emitting layers on the plurality of light-emitting pixel electrodes in the plurality of light-emitting areas; a plurality of photo-sensing layers on the plurality of sensing pixel electrodes in the plurality of photo-sensing areas, the plurality of photo-sensing layers configured to sense light reflected from a user; a common electrode on the pixel defining layer, the plurality of light-emitting layers, and the plurality of photo-sensing layers; an encapsulation layer on the common electrode, the encapsulation layer including at least one organic layer and at least one inorganic layer; a first metalens on the encapsulation layer, the first metalens including a plurality of first nanostructures overlapping the plurality of photo-sensing areas in a thickness direction of the substrate; an intermediate layer on the plurality of first nanostructures; a black matrix in a non-light-emitting area between the plurality of light-emitting areas and the plurality of photo-sensing areas on the intermediate layer; a window member on the black matrix and the intermediate layer; and a second metalens on the window member, the second metalens including a plurality of second nanostructures overlapping the plurality of light-emitting areas in the thickness direction of the substrate.

According to one or more embodiments, the plurality of first nanostructures have a first height, a first width, and a first period.

According to one or more embodiments, the respective first heights of the plurality of first nanostructures are the same as each other.

According to one or more embodiments, the display device further includes a first color filter in the plurality of photo-sensing areas on the encapsulation layer, wherein the first height of each of the plurality of first nanostructures is from 1/10 to 1 times a central wavelength of a first wavelength range transmitted by the first color filter, and wherein the central wavelength is defined as a wavelength of light having the largest intensity from among light passing through the first color filter.

According to one or more embodiments, the first width of each of the plurality of first nanostructures has a value of a first minimum width or more, and a first maximum width or less.

According to one or more embodiments, a first nanostructure of the plurality of first nanostructures having the first maximum width from among the plurality of first nanostructures is arranged at a central portion of the first metalens.

According to one or more embodiments, the plurality of first nanostructures are arranged in a descending order from the first maximum width to the first minimum width within the first period.

According to one or more embodiments, the first period is a distance between the first nanostructures having the first maximum width from among the plurality of first nanostructures.

According to one or more embodiments, the first period decreases from a central portion to an edge of the first metalens.

According to one or more embodiments, a width of the first metalens in a first direction is greater than a width of each of the plurality of photo-sensing areas in the first direction.

According to one or more embodiments, the plurality of second nanostructures includes: first sub-structures arranged in a first light-emitting area configured to emit light of a first color from among the plurality of light-emitting areas; second sub-structures arranged in a second light-emitting area configured to emit light of a second color from among the plurality of light-emitting areas; and third sub-structures arranged in a third light-emitting area configured to emit light of a third color from among the plurality of light-emitting areas.

According to one or more embodiments, the first sub-structures have a second height, a second width, and a second period.

According to one or more embodiments, the display device further includes a first color filter in the first light-emitting area on the encapsulation layer, wherein the second height of each of the first sub-structures is from 1/10 to 1 times a central wavelength of a first wavelength range transmitted by the first color filter.

According to one or more embodiments, the second sub-structures have a third height, a third width, and a third period, and wherein the first sub-structures are different from the second sub-structures.

According to one or more embodiments, the display device further includes a second color filter in the second light-emitting area on the encapsulation layer, wherein the third height of each of the second sub-structures is from 1/10 to 1 times a central wavelength of a second wavelength range transmitted by the second color filter.

According to one or more embodiments, the third sub-structures have a fourth height, a fourth width, and a fourth period, and wherein the third sub-structures are different from the first sub-structures and the second sub-structures.

According to one or more embodiments, the display device further includes a third color filter arranged in the third light-emitting area on the encapsulation layer, wherein the fourth height of each of the third sub-structures is from 1/10 to 1 times a central wavelength of a third wavelength range transmitted by the third color filter.

According to one or more embodiments, a width of the second metalens including the first sub-structures in the thickness direction of the substrate is greater than a width of the first light-emitting area in the thickness direction of the substrate.

According to one or more embodiments, the display device further includes: a plurality of inorganic insulating films on the encapsulation layer; and touch electrodes between the plurality of inorganic insulating films, forming mutual capacitance.

According to one or more embodiments, an electronic device including a display device, the display device includes: a substrate; a plurality of light-emitting pixel electrodes on one side of the substrate; a plurality of sensing pixel electrodes on one surface of the substrate and spaced from the plurality of light-emitting pixel electrodes; a pixel defining layer exposing a portion of each of the plurality of light-emitting pixel electrodes and the plurality of sensing pixel electrodes and defining a plurality of light-emitting areas and a plurality of photo-sensing areas; a plurality of light-emitting layers on the plurality of light-emitting pixel electrodes in the plurality of light-emitting areas; a plurality of photo-sensing layers on the plurality of sensing pixel electrodes in the plurality of photo-sensing areas, the plurality of photo-sensing layers configured to sense light reflected to a user; a common electrode on the pixel defining layer, the plurality of light-emitting layers, and the plurality of photo-sensing layers; an encapsulation layer on the common electrode, the encapsulation layer including at least one organic layer and at least one inorganic layer; a first metalens on the encapsulation layer, the first metalens including a plurality of first nanostructures overlapping the plurality of photo-sensing areas in a thickness direction of the substrate; an intermediate layer on the plurality of first nanostructures; a black matrix in a non-light-emitting area between the plurality of light-emitting areas and the plurality of photo-sensing areas on the intermediate layer; a window member on the black matrix and the intermediate layer; and a second metalens on the window member, the second metalens including a plurality of second nanostructures overlapping the plurality of light-emitting areas in the thickness direction of the substrate.

Aspects of the present disclosure are not limited to those mentioned above and additional aspects of the present disclosure, which are not mentioned herein, will be clearly understood by those skilled in the art from the following description of the present disclosure.

According to some embodiments of the present disclosure, the display device and the electronic device including the same include a first metalens arranged between a plurality of color filters and a black matrix in photo-sensing areas. The light directed toward a non-light-emitting area may be refracted to the photo-sensing areas. This may increase the amount of light received in the photo-sensing areas, thereby enhancing the accuracy of the photo-sensing elements.

According to some embodiments of the present disclosure, the display device and the electronic device including the same include a second metalens arranged on a window member in light-emitting areas. The light that is totally reflected by the window member and is not emitted to the outside of the display device may be emitted to the outside of the display device. This may increase light emission efficiency of the light-emitting elements.

The aspects and features according to the embodiments of the present disclosure are not limited to those mentioned above and more various aspects and features are included in the following description of the present disclosure.

### BRIEF DESCRIPTION THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a perspective view illustrating a display device according to one or more embodiments of the present disclosure;

FIG. 2 is a plan view illustrating an example of the display device of FIG. 1;

FIG. 3 is a side view illustrating an example of the display device of FIG. 1;

FIG. 4 is a plan view illustrating a light-emitting pixel, a photo-sensing pixel, various drivers, and various wirings of the display device of FIG. 1;

FIG. 5 is an enlarged layout view illustrating an area A of FIG. 2;

FIG. 6 is a cross-sectional view taken along the line I-I′ of FIG. 5;

FIG. 7 is a cross-sectional view illustrating the photo-sensing area and the first metalens of FIG. 5;

FIG. 8 is a cross-sectional view illustrating the light-emitting area and the second metalens of FIG. 5;

FIG. 9 is a cross-sectional view illustrating the first and second metalenses of FIG. 5;

FIG. 10 is a graph illustrating a relationship between the wavelength of light transmitted though the color filter of FIG. 5 vs. intensity of light, according to one or more embodiments;

FIG. 11 is a perspective view illustrating a display device according to one or more embodiments of the present disclosure;

FIG. 12 is a plan view illustrating an example of the display device of FIG. 11;

FIG. 13 is a side view illustrating another example of the display device of FIG. 11;

FIG. 14 is a layout view illustrating the touch sensing layer of FIG. 13;

FIG. 15 is an enlarged layout view illustrating an area B of FIG. 14;

FIG. 16 is a cross-sectional view taken along the line J-J′ of FIG. 15;

FIG. 17 is a block diagram illustrating an electronic device including a display device according to one or more embodiments of the present disclosure;

FIG. 18 is a view illustrating electronic devices comprising a display device including an optical filter according to one or more embodiments.

### DETAILED DESCRIPTION

The aspects and features of embodiments of the present disclosure and methods of accomplishing the same may be understood more readily by reference to the detailed description of embodiments and the accompanying drawings. Hereinafter, the subject matter of the present disclosure will be described in more detail with reference to the accompanying drawings, in which embodiments of the present disclosure are shown. In this regard, the subject matter of the present disclosure may be embodied in different forms and should not be construed as being limited to one or more embodiments set forth herein. Rather, these embodiments are provided as examples so that the present disclosure will be thorough and complete and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals, characters, and/or one or more (e.g., any suitable) combinations thereof denote like elements throughout the attached drawings and the written description, and duplicative descriptions thereof may not be provided, and thus, descriptions thereof will not be repeated. Further, parts not related to the description of one or more embodiments may not be shown to make the description clear.

In the drawings, the relative sizes of elements, layers, and regions may be exaggerated to effectively or suitably illustrate the technical contents of the present disclosure. Also, cross-hatching and/or shading in the accompanying drawings may be used to clarify boundaries between adjacent elements. As such, neither the presence nor the absence of cross-hatching and/or shading conveys nor indicates any preference or requirement for certain materials, material properties, dimensions, proportions, commonalities between illustrated elements, and/or any other characteristic, attribute, property, and/or the like of the elements, unless specified.

One or more embodiments of the present disclosure are described herein with reference to sectional illustrations that are schematic illustrations of embodiments and/or intermediate structures. As such, variations from the shapes of the illustrations as a result, for example, of manufacturing techniques and/or tolerances, may be expected. Further, specific structural or functional descriptions disclosed herein are just illustrative for the purpose of describing one or more embodiments of the present disclosure. Thus, one or more embodiments disclosed herein should not be construed as being limited to the specific shapes of regions, but should be construed to include deviations in shapes that result from, for instance, manufacturing. As such, the shapes shown in the drawings may not depict the actual shapes of regions of the device, and embodiments of the present disclosure are not limited thereto.

For example, an implanted region illustrated as a rectangle (e.g., a substantially rectangle) may have rounded or curved features and/or a gradient of implant concentration at its edges rather than a binary change from implanted to non-implanted region. Likewise, a buried region formed or provided by implantation may result in an implantation in the region between the buried region and the surface through which the implantation takes place. Thus, the regions illustrated in the drawings are schematic in nature, and their shapes are not intended to illustrate the actual shape of a region of a device and are not intended to be limiting. Also, as those skilled in the art would realize, the present disclosure may be modified in one or more suitable different ways, all without departing from the spirit or scope of the present disclosure.

In the present disclosure, for the purposes of explanation, one or more specific details are set forth to provide a thorough understanding of one or more embodiments. It is apparent, however, that one or more embodiments may be practiced without these specific details or with one or more equivalent arrangements. In other instances, structures and devices that are generally available or generally used are shown in block diagram form to avoid unnecessarily obscuring one or more embodiments.

Spatially relative terms, such as “beneath,” “below,” “lower,” “under,” “above,” “upper,” and/or the like, may be used herein for ease of explanation to describe the relationship of one element or feature to another element(s) or feature(s) as illustrated in the drawings. It will be understood that the spatially relative terms are intended to encompass different orientations of the device in use or in operation, in addition to the orientation depicted in the drawings. For example, if the device in the drawings is turned over, elements described as “below,” “beneath,” or “under” other elements or features may then be oriented “above” the other elements or features. Thus, the example terms “below” and “under” may encompass both (e.g., concurrently (e.g., simultaneously)) an orientation of above and below. The device may be otherwise oriented (e.g., rotated 90 degrees or at other orientations), and the spatially relative descriptors used herein should be interpreted accordingly. Similarly, if (e.g., when) a first part is described as being “on” a second part, this indicates that the first part is at an upper side or a lower side of the second part without the limitation to the upper side thereof on the basis of the gravity direction.

Further, in the present disclosure, the phrase “on a plane” or “in a plan view” refers to viewing a target portion from the top, and the phrase “on a cross-section” or “in a cross-sectional view” refers to viewing a cross-section formed by vertically cutting a target portion from the side.

It will be understood that if (e.g., when) an element, a layer, a region, or a component is referred to as being “formed or provided on,” “on,” “connected to,” or “coupled to” another element, layer, region, or component, it may be directly formed or provided on, on, connected to, or coupled to the other element, layer, region, or component, or indirectly formed or provided on, on, connected to, or coupled to the other element, layer, region, or component such that one or more intervening elements, layers, regions, or components may be present therebetween. For example, if (e.g., when) a layer, a region, or a component is referred to as being “electrically connected” or “electrically coupled” to another layer, region, or component, it may be directly electrically connected or coupled to the other layer, region, and/or component or intervening layers, regions, or components may be present therebetween. However, “directly connected/directly coupled” refers to one component directly connecting or coupling another component without an (e.g., any) intermediate component. In one or more embodiments, other expressions describing relationships between components, such as “between,” “immediately between,” “adjacent to,” and “directly adjacent to,” may be construed similarly. In one or more embodiments, it will also be understood that if (e.g., when) an element or a layer is referred to as being “between” two elements or layers, it may be the only element or layer between the two elements or layers, or one or more intervening elements or layers may also be present therebetween.

In the present disclosure, expressions, such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from among the group consisting of X, Y, and Z” may be construed as X only, Y only, Z only, any combination of two or more of X, Y, and Z, such as, for instance, XYZ, XYY, XZ, YZ, and ZZ, or a (e.g., any suitable) variation thereof. Similarly, the expression, such as “at least one of A and/or B,” may include A, B, or A and B.

As used herein, the term “and/or” includes any and all combinations of one or more of the associated listed items. For example, the expression, such as “A and/or B,” may include A, B, or A and B. Further, the use of “may” if (e.g., when) describing embodiments of the present disclosure refers to “one or more embodiments of the present disclosure.”

It will be understood that, although the terms “first,” “second,” “third,” and/or the like may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section described in more detail could be termed a second element, a second component, a second region, a second layer, or a second section without departing from the spirit and scope of the present disclosure.

In the examples, the x-axis, the y-axis, and/or the z-axis are not limited to three axes of a rectangular coordinate system and may be interpreted in a broader sense. For example, the x-axis, the y-axis, and the z-axis may be normal (e.g., perpendicular) to one another or may represent different directions that are not normal (e.g., perpendicular) to one another. Substantially the same applies for a first direction, a second direction, and/or a third direction.

The terminology used herein is for the purpose of describing certain embodiments only and is not intended to be limiting of the present disclosure. As used herein, the singular forms “a” and “an” are intended to include the plural forms as well, unless the context clearly indicates otherwise.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “substantially,” “about,” “approximately,” and similar terms are used as terms of approximation and not as terms of degree and are intended to account for the inherent deviations in measured or calculated values that would be recognized by those of ordinary skill in the art. “About” or “approximately,” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value. Further, the use of “may” if (e.g., when) describing one or more embodiments of the present disclosure refers to “one or more embodiments of the present disclosure.”

If (e.g., when) one or more embodiments may be implemented differently, a set or specific process order may be performed differently from the described order. For example, two consecutively described processes may be performed at substantially the same time or performed in an order opposite to the described order.

Also, any numerical range disclosed and/or recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic devices, the electric devices, manufacturing devices thereof, and/or any other relevant devices or components according to one or more embodiments of the present disclosure may be implemented by utilizing any suitable hardware, firmware (e.g., an application-specific integrated circuit), software, and/or a (e.g., any suitable) combination of software, firmware, and hardware. For example, the one or more suitable components of these devices may be formed or provided on one integrated circuit (IC) chip or on separate IC chips. Further, the one or more suitable components of these devices may be implemented on a flexible printed circuit film, a tape carrier package (TCP), a printed circuit board (PCB), or formed or provided on one substrate.

Further, the one or more suitable components of these devices may be a process or thread, running on one or more processors, in one or more computing devices, executing computer program instructions, and interacting with other system components to perform the one or more suitable functionalities as described herein. The computer program instructions may be stored in a memory which may be implemented in a computing device by using a standard memory device, such as, for example, a random access memory (RAM). The computer program instructions may also be stored in other non-transitory computer readable media, such as, for example, a CD-ROM, a flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

In the context of the present application and unless otherwise defined, the terms “use,” “using,” and “used” may be considered synonymous with the terms “utilize,” “utilizing,” and “utilized,” respectively. Further, the use of “may” when describing embodiments of the inventive concept refers to “one or more embodiments of the inventive concept.”

Unless otherwise defined, all terms (including technical and scientific terms) used herein have substantially the same meaning as commonly understood by one of ordinary skill in the art to which the present disclosure belongs. It will be further understood that terms, such as those defined in dictionaries, that are generally available or generally used, should be interpreted as having a meaning that is consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, one or more embodiments will be described in more detail with reference to the accompanying drawings.

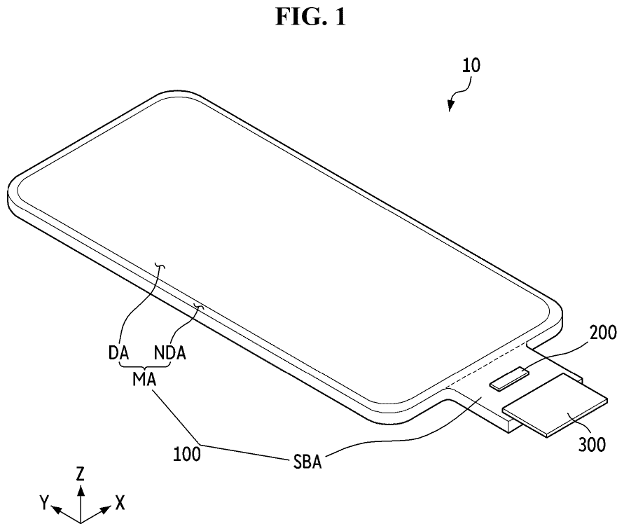

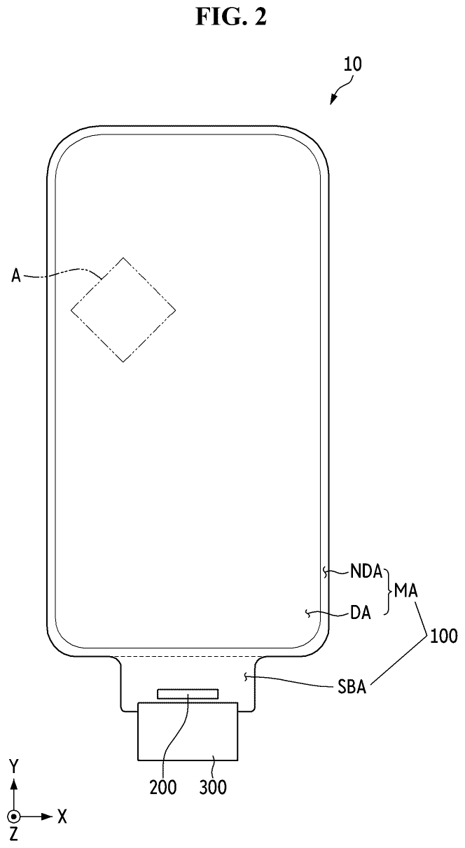

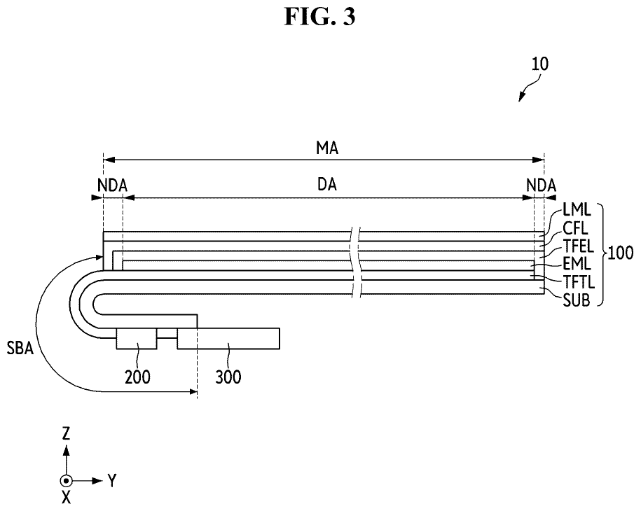

FIG. 1 is a perspective view illustrating a display device according to one or more embodiments of the present disclosure. FIG. 2 is a plan view illustrating an example of the display device of FIG. 1. FIG. 3 is a side view illustrating an example of the display device of FIG. 1.

Referring to FIG. 1-3, a display device 10 according to one or more embodiments may be applied to a mobile electronic device such as a mobile phone, a smart phone, a tablet personal computer (PC), a mobile communication terminal, an electronic diary, an electronic book, a portable multimedia player (PMP), a navigator and an ultra-mobile PC (UMPC). Otherwise, the display device 10 according to one or more embodiments may be applied to a television, a laptop computer, a monitor, a signboard or a display unit of Internet of things (IoT). Otherwise, the display device 10 according to one or more embodiments may be applied to a wearable device such as a smart watch, a watch phone, an eyeglasses-type display, and/or a head mounted display (HMD). Otherwise, the display device 10 according to one or more embodiments may be applied to a dashboard of a vehicle, a center fascia of a vehicle, a center information display (CID) arranged in a dashboard of a vehicle, a room mirror display that replaces a side mirror of a vehicle or a display arranged on a rear surface of a front seat as an entertainment for a rear seat of a vehicle.

The display device 10 may be an organic light-emitting display device using an organic light-emitting diode (OLED), a quantum dot light-emitting display device including a quantum dot light-emitting layer, an inorganic light-emitting display device including an inorganic semiconductor, or a micro or nano light-emitting display device using a micro or nano light-emitting diode (micro LED or nano LED). The following description will be based on that the display device 10 is an organic light-emitting display device, but the present disclosure is not limited thereto.

The display device 10 may include a display panel 100, a display driving circuit 200, and a display circuit board 300.

The display panel 100 may be formed as a rectangular plane having a short side in a first direction (X-axis direction) and a long side in a second direction (Y-axis direction) crossing the first direction (X-axis direction). A corner where the short side in the first direction (X-axis direction) and the long side in the second direction (Y-axis direction) meet may be rounded to have a curvature or formed at a right angle. A planar shape of the display panel 100 is not limited to a rectangular shape, and may be formed in another polygonal shape, a circular shape, or an oval shape. The display panel 100 may be formed to be flat, but is not limited thereto. The display panel 100 may include a curved portion formed at left and right ends, having a constant curvature or a variable curvature. In addition, the display panel 100 may be flexibly formed to be curved, twisted, bent, folded, and/or rolled.

The display panel 100 includes a main area MA and a sub-area SBA.

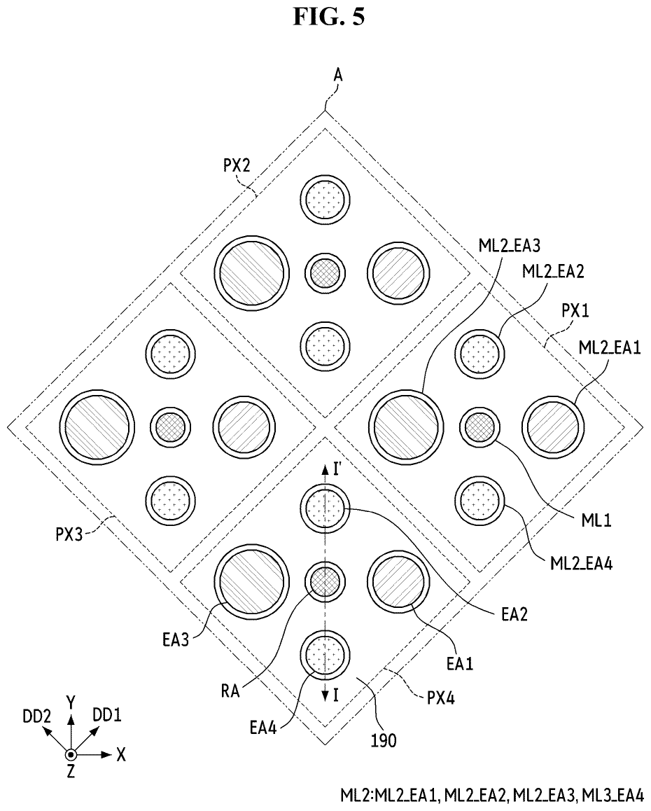

The main area MA includes a display area DA for displaying an image and a non-display area NDA that is a peripheral area of the display area DA. The display area DA includes pixels PX1 to PX4 of FIG. 5 for displaying an image. The sub-area SBA may protrude from one side of the main area MA in a direction opposite to the second direction (Y-axis direction).

Although FIGS. 1 and 2 illustrate that the sub-area SBA is unfolded, the sub-area SBA may be bent as shown in FIG. 3, and in this case, the sub-area SBA may be arranged on the lower surface of the display panel 100. When the sub-area SBA is bent, the sub-area SBA may overlap the main area MA in a thickness direction (Z-axis direction) of a substrate SUB. The display driving circuit 200 may be arranged in the sub-area SBA.

Also, as shown in FIG. 3, the display panel 100 may include a substrate SUB, a thin film transistor layer TFTL, a light-emitting element layer EML, an encapsulation layer TFEL, a color filter layer CFL, and a light modulation layer LML.

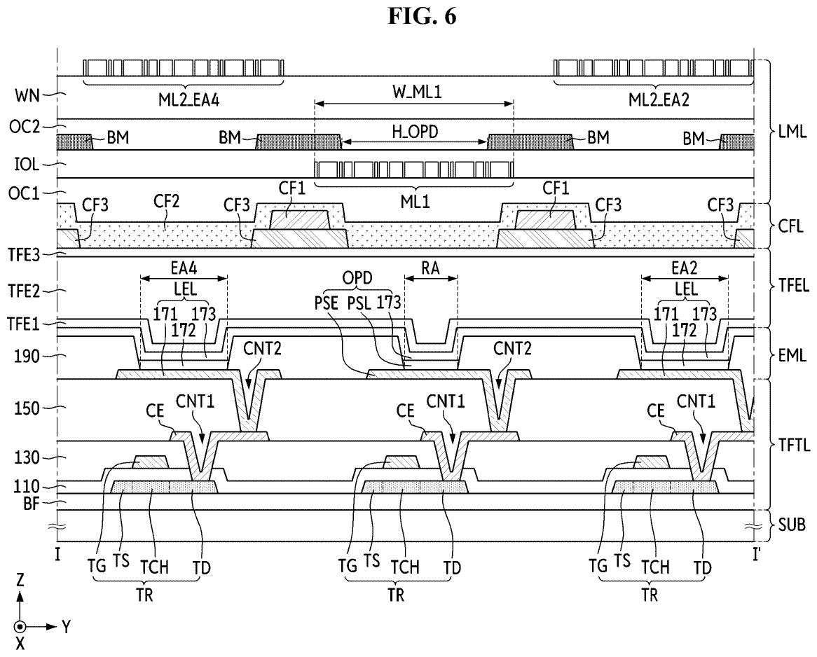

The thin film transistor layer TFTL may be arranged on the substrate SUB. The thin film transistor layer TFTL may be arranged in the main area MA and the sub-area SBA. The thin film transistor layer TFTL includes transistors TR of FIG. 6.

The light-emitting element layer EML may be arranged on the thin film transistor layer TFTL. The light-emitting element layer EML may be arranged in the display area DA of the main area MA. The light-emitting element layer EML includes light-emitting elements arranged in light-emitting areas. Also, the light-emitting element layer EML includes photo-sensing elements arranged in photo-sensing areas.

The encapsulation layer TFEL may be arranged on the light-emitting element layer EML. The encapsulation layer TFEL may be arranged in the display area DA and the non-display area NDA of the main area MA. The encapsulation layer TFEL includes at least one inorganic layer and at least one organic layer to encapsulate the light-emitting element layer.

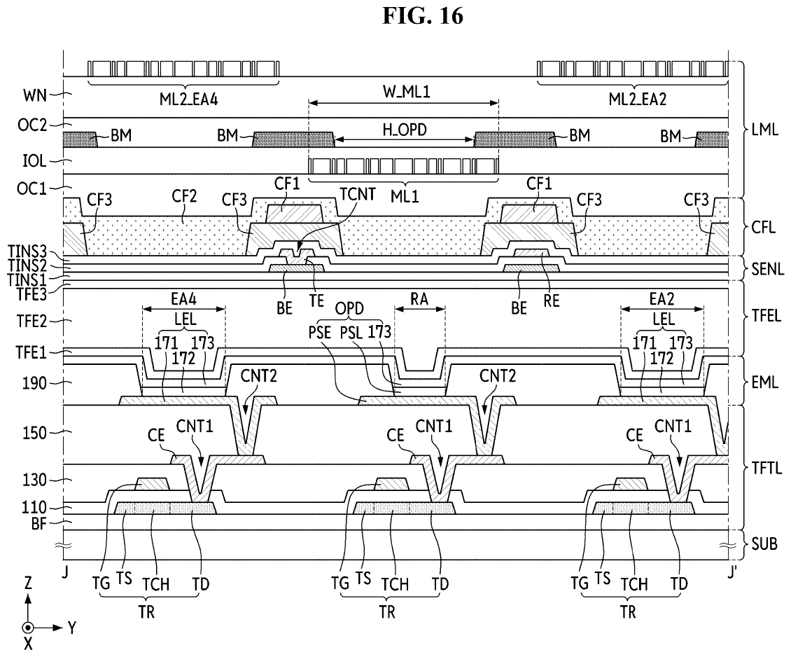

A color filter layer CFL may be arranged on the encapsulation layer TFEL. In one or more embodiments, the color filter layer CFL may be arranged on a touch sensing layer SENL (e.g., see FIG. 16). The color filter layer CFL may be arranged in the display area DA and the non-display area NDA of the main area MA. The color filter layer CFL may be an anti-reflective member for reducing reflection of external light from metal lines and metal electrodes of the display panel 100. The color filter layer CFL includes a plurality of color filters. For example, the color filter layer CFL includes a first color filter that transmits light in a first wavelength range, a second color filter that transmits light in a second wavelength range, and a third color filter that transmits light in a third wavelength range.

The light modulation layer LML may be arranged on the color filter layer CFL. The light modulation layer LML may be arranged in the display area DA and the non-display area NDA of the main area MA. The light modulation layer LML may include an optical member for increasing light emission efficiency of light emitted from the light-emitting elements of the light-emitting element layer EML. Also, the light modulation layer LML may include an optical member for increasing the amount of light received in the photo-sensing elements of the light-emitting element layer EML.

The display driving circuit 200 may generate signals and voltages for driving the display panel 100. The display driving circuit 200 may be formed as an integrated circuit (IC) and attached onto the display panel 100 by a chip on glass (COG) mode, a chip on plastic (COP) mode, or an ultrasonic bonding mode, but is not limited thereto. For example, the display driving circuit 200 may be attached onto the display circuit board 300 by a chip on film (COF) mode.

The display circuit board 300 may be attached to one end of the sub-area SBA of the display panel 100. For this reason, the display circuit board 300 may be electrically connected to the display panel 100 and the display driving circuit 200. The display panel 100 and the display driving circuit 200 may receive digital video data, timing signals, and driving voltages through the display circuit board 300. The display circuit board 300 may be a flexible printed circuit board (FPCB), a printed circuit board(PCB), or a flexible film such as a chip on film.

As shown in FIG. 1-3, in order to reduce reflection of external light by metal lines and metal electrodes of the display panel 100, the display panel 100 includes a color filter layer CFL including color filters. Accordingly, because it is not necessary to attach a separate anti-reflective member such as a polarizing plate onto the display panel 100, manufacturing costs of the display device 10 may be reduced, but the present disclosure is not limited thereto. In one or more embodiments, a polarizing plate may be provided instead of the color filter layer CFL.

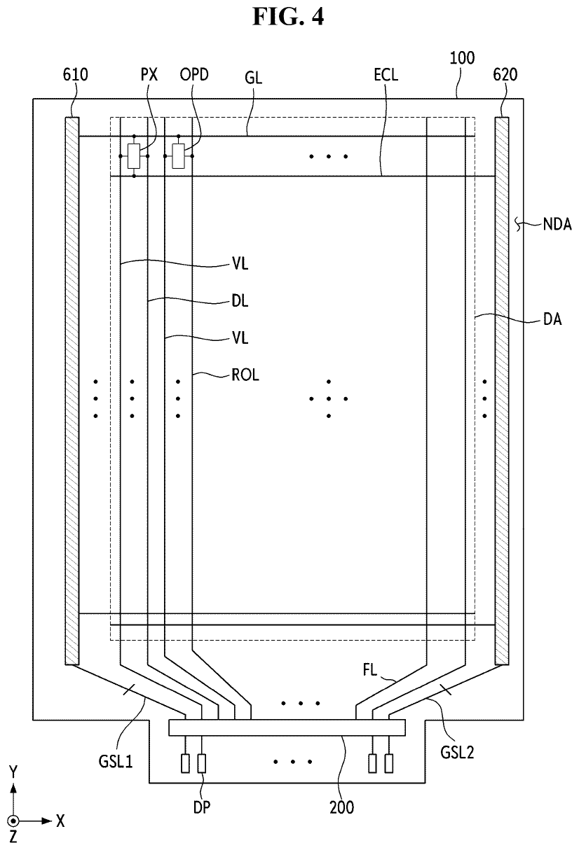

FIG. 4 is a plan view illustrating a light-emitting pixel, a photo-sensing pixel, various drivers, and various wirings of the display device of FIG. 1.

Referring to FIG. 4, the display panel 100 may include a display area DA and a non-display area NDA disposed along an edge or a periphery of the display area DA. The display area DA may include light-emitting pixels PX, photo-sensing pixels OPD, a power line VL, a data line DL, a read-out line ROL, a gate line GL, and an emission control line ECL.

Each of the plurality of light-emitting pixels PX may be connected to the gate line GL, the emission control line ECL, the data line DL, and the power line VL. Each of the plurality of light-emitting pixels PX may include a plurality of transistors, a light-emitting element, and a capacitor.

Each of the plurality of photo-sensing pixels OPD may be connected to the gate line GL, the power line VL, and the read-out line ROL. Each of the plurality of photo-sensing pixels OPD may include a plurality of transistors and photo-sensing elements. For example, the plurality of photo-sensing pixels OPD may be used to derive biometric information such as a user's fingerprint or pulse by sensing light reflected toward the user.

The gate lines GL may extend in the first direction (X-axis direction), and may be spaced (e.g., spaced apart) from each other in the second direction (Y-axis direction) crossing the first direction (X-axis direction). The gate lines GL may sequentially supply gate signals to the light-emitting pixels PX and the photo-sensing pixels OPD.

The emission control lines ECL may extend in the first direction (X-axis direction), and may be spaced (e.g., spaced apart) from each other in the second direction (Y-axis direction). The emission control lines ECL may sequentially supply light-emitting signals to the light-emitting pixels PX.

The data lines DL may extend in the second direction (Y-axis direction), and may be spaced (e.g., spaced apart) from each other in the first direction (X-axis direction). The data lines DL may supply a data voltage to the light-emitting pixels PX. The data voltage may determine luminance of each of the light-emitting pixels PX.

The power lines VL may extend in the second direction (Y-axis direction), and may be spaced (e.g., spaced apart) from each other in the first direction (X-axis direction). The power lines VL may supply a power voltage to the light-emitting pixels PX and the photo-sensing pixels OPD. The power voltage may be a driving voltage, a common voltage, an initialization voltage, a reference voltage, a bias voltage, and/or a reset voltage. The driving voltage may be a high potential voltage for driving the light-emitting pixel PX, and the common voltage may be a low potential voltage for driving the photo-sensing pixel OPD.

The read-out lines ROL may extend in the second direction (Y-axis direction), and may be spaced (e.g., spaced apart) from each other in the first direction (X-axis direction). The read-out lines ROL may read out sensing signals for sensing light from the photo-sensing pixels OPD.

The non-display area NDA may be around (e.g., may surround) the display area DA. The non-display area NDA may include a gate driver 610, a light emission control driver 620, fan-out lines FL, a first gate control line GSL1, and a second gate control line GSL2.

The fan-out lines FL may extend from the display driving circuit 200 to the display area DA. The fan-out lines FL may supply the data voltage received from the display driving circuit 200 to the data line DL, the power voltage received from the display driving circuit 200 to the power line VL, and the sensing signal received from the read-out line ROL to the display driving circuit 200. Accordingly, the display driving circuit 200 may drive the light-emitting pixel PX and the photo-sensing pixel OPD.

The first gate control line GSL1 may extend from the display driving circuit 200 to the gate driver 610. The first gate control line GSL1 may supply a gate control signal received from the display driving circuit 200 to the gate driver 610.

The second gate control line GSL2 may extend from the display driving circuit 200 to the light emission control driver 620. The second gate control line GSL2 may supply a light emission control signal received from the display driving circuit 200 to the light emission control driver 620.

The gate driver 610 may be arranged outside one side of the display area DA or on one side of the non-display area NDA. The gate driver 610 may include a plurality of transistors that generate a gate signal based on the gate control signal.

The light emission control driver 620 may be arranged outside the other side of the display area DA or on the other side of the non-display area NDA. The light emission control driver 620 may include a plurality of transistors that generate light-emitting signals based on the light emission control signal.

For example, the transistors of the gate driver 610 and the transistors of the light emission control driver 620 may be formed on (e.g., at) the same layer as the transistors of each of the light-emitting pixels PX. The gate driver 610 may supply gate signals to the gate lines GL, and the light emission control driver 620 may supply the light-emitting signals to the emission control lines ECL.

The sub-display area SBA may extend from one side of the non-display area NDA. The sub-display area SBA may include a display driving circuit 200 and a pad portion DP. The pad portion DP may be arranged more adjacent to one edge of the sub-area SBA than the display driving circuit 200. The pad portion DP may be electrically connected to the display circuit board 300 through an anisotropic conductive film.

FIG. 5 is an enlarged layout view illustrating an area A of FIG. 2.

Referring to FIG. 5, the display panel 100 may include a plurality of light-emitting pixels PX and a plurality of photo-sensing pixels OPD.

For example, the plurality of light-emitting pixels PX may include first to fourth light-emitting pixels PX1 to PX4. Each of the plurality of photo-sensing pixels OPD may be arranged approximately at a center of each of the first to fourth light-emitting pixels PX1 to PX4. Although FIG. 5 illustrates that the plurality of light-emitting pixels PX correspond to the plurality of photo-sensing pixels OPD on a one-to-one basis, the present disclosure is not limited thereto. One light-emitting pixel PX may correspond to the plurality of photo-sensing pixels OPD, or the plurality of light-emitting pixels PX may correspond to one photo-sensing pixel OPD.

The first to fourth light-emitting pixels PX1 to PX4 may be arranged adjacent to each other in a first diagonal direction DD1 and a second diagonal direction DD2. The first diagonal direction DD1 may be a direction crossing the first direction (X-axis direction) and the second direction (Y-axis direction) on a plane formed by the first direction (X-axis direction) and the second direction (Y-axis direction). The second diagonal direction DD2 may be a direction crossing the first direction (X-axis direction), the second direction (Y-axis direction), and the first diagonal direction DD1 on a plane formed by the first direction (X-axis direction) and the second direction (Y-axis direction). For example, an angle formed by the first diagonal direction DD1 and the second diagonal direction DD2 may be 90°, but the present disclosure is not limited thereto.

Each of the first to fourth light-emitting pixels PX1 to PX4 may include light-emitting areas EA1 to EA4. For example, each of the first to fourth light-emitting pixels PX1 to PX4 may include a first light-emitting area EA1, a second light-emitting area EA2, a third light-emitting area EA3, and a fourth light-emitting area EA4, but the present disclosure is not limited thereto, and the number of light-emitting areas included in one light-emitting pixel PX may be modified.

The first light-emitting area EA1 may emit light of a first color. The first color is red, and a peak wavelength of the light of the first color may be included in a wavelength band of about 600 nm to about 750 nm.

The second light-emitting area EA2 may emit light of a second color. The second color is green, and a peak wavelength of the light of the second color may be included in a wavelength band of about 500 nm to about 570 nm.

The third light-emitting area EA3 may emit light of a third color. The third color is blue, and a peak wavelength of the light of the third color may be included in a wavelength band of about 430 nm to about 490 nm.

The fourth light-emitting area EA4 may emit light of a second color in the same manner as the second light-emitting area EA2.

For example, the light-emitting areas EA1 to EA4 may be arranged in a PENTILE® type arrangement. PENTILE® is a registered trademark of Samsung Display Co., Ltd., Republic of Korea. The first light-emitting area EA1 may be arranged to be spaced (e.g., spaced apart) from the second light-emitting area EA2 in the second diagonal direction DD2. The first light-emitting area EA1 may be arranged to be spaced (e.g., spaced apart) from the third light-emitting area EA3 in the first direction (X-axis direction). The first light-emitting area EA1 may be arranged to be spaced (e.g., spaced apart) from the fourth light-emitting area EA4 in the first diagonal direction DD1. The second light-emitting area EA2 may be arranged to be spaced (e.g., spaced apart) from the third light-emitting area EA3 in the first diagonal direction DD1. The second light-emitting area EA2 may be arranged to be spaced (e.g., spaced apart) from the fourth light-emitting area EA4 in the second direction (Y-axis direction). The third light-emitting area EA3 may be arranged to be spaced (e.g., spaced apart) from the fourth light-emitting area EA4 in the second diagonal direction DD2.

Although a planar shape of the light-emitting areas EA1 to EA4 is shown as a circular shape by way of example, the present disclosure is not limited thereto. Various modifications such as an oval shape and a rectangular shape may be made in the planar shape of the light-emitting areas EA1 to EA4.

Sizes of the light-emitting areas EA1 to EA4 may be different from one another. For example, the size of the first light-emitting area EA1 may be larger than the size of the second light-emitting area EA2 and smaller than the size of the third light-emitting area EA3. The size of the second light-emitting area EA2 may be the same as the size of the fourth light-emitting area EA4. However, the present disclosure is not limited to the above example, and the sizes of the light-emitting areas EA1 to EA4 may be freely adjusted.

Second metalenses ML2_EA1 to ML2_EA4 may be arranged in the light-emitting areas EA1 to EA4. The second metalenses ML2_EA1 to ML2_EA4 may include a plurality of second nanostructures. The second metalenses ML2_EA1 to ML2_EA4 may include the first sub-lens ML2_EA1 arranged in the first light-emitting area EA1, the second sub-lens ML2_EA2 arranged in the second light-emitting area EA2, the third sub-lens ML2_EA3 arranged in the third light-emitting area EA3, and the fourth sub-lens ML2_EA4 arranged in the fourth light-emitting area EA4.

The first sub-lens ML2_EA1 may overlap the first light-emitting area EA1 in the third direction (Z-axis direction). A planar shape of the first sub-lens ML2_EA1 may follow the planar shape of the first light-emitting area EA1. For example, the planar shape of the first sub-lens ML2_EA1 and the planar shape of the first light-emitting area EA1 may be circular. A size of the first sub-lens ML2_EA1 may be greater than or equal to the size of the first light-emitting area EA1. For example, a maximum length of the first sub-lens ML2_EA1 in the first direction (X-axis direction) may be greater than or equal to a maximum length of the first light-emitting area EA1 in the first direction (X-axis direction). A maximum length of the first sub-lens ML2_EA1 in the second direction (Y-axis direction) may be greater than or equal to a maximum length of the first light-emitting area EA1 in the second direction (Y-axis direction). For the first diagonal direction DD1 and the second diagonal direction DD2, the maximum length of the first sub-lens ML2_EA1 may be greater than or equal to the maximum length of the first light-emitting area EA1.

The second sub-lens ML2_EA2 may overlap the second light-emitting area EA2 in the third direction (Z-axis direction). A planar shape of the second sub-lens ML2_EA2 may follow the planar shape of the second light-emitting area EA2. For example, the planar shape of the second sub-lens ML2_EA2 and the planar shape of the second light-emitting area EA2 may be circular. A size of the second sub-lens ML2_EA2 may be greater than or equal to the size of the second light-emitting area EA2. For example, a maximum length of the second sub-lens ML2_EA2 in the first direction (X-axis direction) may be greater than or equal to a maximum length of the second light-emitting area EA2 in the first direction (X-axis direction). A maximum length of the second sub-lens ML2_EA2 in the second direction (Y-axis direction) may be greater than or equal to a maximum length of the second light-emitting area EA2 in the second direction (Y-axis direction). For the first diagonal direction DD1 and the second diagonal direction DD2, the maximum length of the second sub-lens ML2_EA2 may be greater than or equal to the maximum length of the second light-emitting area EA2.

The third sub-lens ML2_EA3 may overlap the third light-emitting area EA3 in the third direction (Z-axis direction). A planar shape of the third sub-lens ML2_EA3 may follow the planar shape of the third light-emitting area EA3. For example, the planar shape of the third sub-lens ML2_EA3 and the planar shape of the third light-emitting area EA3 may be circular. A size of the third sub-lens ML2_EA3 may be greater than or equal to the size of the third light-emitting area EA3. For example, a maximum length of the third sub-lens ML2_EA3 in the first direction (X-axis direction) may be greater than or equal to a maximum length of the third light-emitting area EA3 in the first direction (X-axis direction). A maximum length of the third sub-lens ML2_EA3 in the second direction (Y-axis direction) may be greater than or equal to a maximum length of the third light-emitting area EA3 in the second direction (Y-axis direction). For the first diagonal direction DD1 and the second diagonal direction DD2, the maximum length of the third sub-lens ML2_EA3 may be greater than or equal to the maximum length of the third light-emitting area EA3.

The fourth sub-lens ML2_EA4 may overlap the fourth light-emitting area EA4 in the third direction (Z-axis direction). A planar shape of the fourth sub-lens ML2_EA4 may follow the planar shape of the fourth light-emitting area EA4. For example, the planar shape of the fourth sub-lens ML2_EA4 and the planar shape of the fourth light-emitting area EA4 may be circular. A size of the fourth sub-lens ML2_EA4 may be greater than or equal to the size of the fourth light-emitting area EA4. For example, a maximum length of the fourth sub-lens ML2_EA4 in the first direction (X-axis direction) may be greater than or equal to a maximum length of the fourth light-emitting area EA4 in the first direction (X-axis direction). A maximum length of the fourth sub-lens ML2_EA4 in the second direction (Y-axis direction) may be greater than or equal to a maximum length of the fourth light-emitting area EA4 in the second direction (Y-axis direction). For the first diagonal direction DD1 and the second diagonal direction DD2, the maximum length of the fourth sub-lens ML2_EA4 may be greater than or equal to the maximum length of the fourth light-emitting area EA4.

A plurality of second nanostructures may include first to fourth sub-structures. The first sub-lens ML2_EA1 may include first sub-structures. The second sub-lens ML2_EA2 may include second sub-structures. The third sub-lens ML3_EA3 may include third sub-structures. The fourth sub-lens ML4_EA4 may include fourth sub-structures.

The first sub-structures may be formed to be suitable for light of the first color, which is emitted from the first light-emitting area EA1. The second sub-structures may be formed to be suitable for light of the second color, which is emitted from the second light-emitting area EA2. The third sub-structures may be formed to be suitable for light of the third color, which is emitted from the third light-emitting area EA3. The fourth sub-structures may be formed to be suitable for light of the second color, which is emitted from the fourth light-emitting area EA4. Thus, the second sub-structures and the fourth sub-structures may be formed substantially the same as each other. Detailed shapes of the first sub-structure, the second sub-structure, and the third sub-structure may be different from one another.

Each of the plurality of photo-sensing pixels OPD may include a photo-sensing area RA. The photo-sensing area RA may sense light reflected from a user. The photo-sensing area RA may be surrounded by the light-emitting areas EA1 to EA4. For example, the photo-sensing area RA may be arranged in the middle of the light-emitting areas EA1 to EA4. The photo-sensing area RA may be arranged between the first light-emitting area EA1 and the third light-emitting area EA3 in the first direction (X-axis direction). The photo-sensing area RA may be arranged between the second light-emitting area EA2 and the fourth light-emitting area EA4 in the second direction (y-axis direction).

The photo-sensing areas RA may be arranged to be spaced (e.g., spaced apart) from each other with at least one of the light-emitting areas EA1 to EA4 interposed between the photo-sensing areas RA. For example, the photo-sensing areas RA may be arranged to be spaced (e.g., spaced apart) from each other with the first and third light-emitting areas EA1 and EA3 interposed between the photo-sensing areas RA in the first direction (X-axis direction). The photo-sensing areas RA may be arranged to be spaced (e.g., spaced apart) from each other with the second and fourth light-emitting area EA2 and EA4 interposed between the photo-sensing areas RA in the second direction (Y-axis direction).

Although the planar shape of the photo-sensing areas RA is shown as being circular, the present disclosure is not limited thereto. Various modifications such as an oval shape and a rectangular shape may be made in the planar shape of the photo-sensing areas RA.

A first metalens ML1 may be arranged in the photo-sensing areas RA. The first metalens ML1 may include a plurality of first nanostructures. The first metalens ML1 may overlap the photo-sensing area RA in the third direction (Z-axis direction). The planar shape of the first metalens ML1 may follow the planar shape of the photo-sensing area RA. For example, when the planar shape of the photo-sensing area RA is circular, the planar shape of the first metalens ML1 may also be circular. A size of the first metalens ML1 may be greater than or equal to a size of the photo-sensing area RA. For example, a maximum length of the first metalens ML1 in the first direction (X-axis direction) may be greater than or equal to a maximum length of the photo-sensing area RA in the first direction (X-axis direction). A maximum length of the first metalens ML1 in the second direction (Y-axis direction) may be greater than or equal to a maximum length of the photo-sensing area RA in the second direction (Y-axis direction). For the first diagonal direction DD1 and the second diagonal direction DD2, the maximum length of the first metalens ML1 may be greater than or equal to the maximum length of the photo-sensing area RA.

FIG. 6 is a cross-sectional view taken along the line I-I′ of FIG. 5.

Referring to FIG. 6, the display panel 100 may include a substrate SUB, a thin film transistor layer TFTL, a light-emitting element layer EML, an encapsulation layer TFEL, a color filter layer CFL, and a light modulation layer LML.

The substrate SUB may include an insulating material such as glass, quartz, and/or polymer resin. Alternatively, the substrate SUB may also include a metal material. The substrate SUB may be a rigid substrate or a flexible substrate capable of being subjected to bending, folding, rolling, etc. When the substrate SUB is a flexible substrate, the substrate may include polyimide (PI), but is not limited thereto.

The thin film transistor layer TFTL may be arranged on the substrate SUB. The thin film transistor layer TFTL may include thin film transistors TR of each of light-emitting pixels and sensing pixels, a connection electrode CE, and a plurality of insulating layers.

In detail, a buffer film BF may be arranged on the substrate SUB. The buffer film BF may include a plurality of inorganic films that are alternately stacked. For example, the buffer film BF may include a multi-layer in which one or more inorganic layers of a silicon nitride layer, a silicon oxynitride layer, a silicon oxide layer, a titanium oxide layer, and/or an aluminum oxide layer are alternately stacked.

An active layer of each of the thin film transistors TR may be arranged on the buffer film BF. The active layer includes a channel TCH, a source electrode TS, and a drain electrode TD.

A gate insulating film 110 may be arranged on the active layer and the buffer film BF. The gate insulating film 110 may include an inorganic insulating film, for example, a silicon nitride film (SiNx), a silicon oxide film (SiOx), a silicon nitride oxide film (SiON), a titanium oxide film (TiOx), and/or an aluminum oxide film (AlOx).

A gate electrode TG of the transistor TR may be arranged on the gate insulating film 110. The gate electrode TG may overlap the channel TCH in the third direction (Z-axis direction). The gate electrode TG may be formed as a single layer or multi-layer made of molybdenum (Mo), aluminum (Al), chromium (Cr), gold (Au), titanium (Ti), nickel (Ni), neodymium (Nd), and/or copper (Cu), and/or their alloy.

An interlayer insulating layer 130 may be arranged on the gate electrode TG of the transistor TR and on the gate insulating film 110. The interlayer insulating layer 130 may include an inorganic layer, for example, a silicon nitride layer, a silicon oxynitride layer, a silicon oxide layer, a titanium oxide layer, and/or an aluminum oxide layer. The interlayer insulating layer 130 may include a plurality of inorganic layers.

A first source metal layer may be arranged on the interlayer insulating layer 130. The first source metal layer includes the connection electrode CE. The connection electrode CE may be connected to the drain electrode TD of the transistor TR through a first contact hole CNT1 passing through the gate insulating film 110 and the interlayer insulating layer 130. The connection electrode CE may be formed as a single layer or multi-layer made of molybdenum (Mo), aluminum (Al), chromium (Cr), gold (Au), titanium (Ti), nickel (Ni), neodymium (Nd), and/or copper (Cu), and/or their alloy.

A passivation layer 150 may be arranged on the first source metal layer and the interlayer insulating layer 130 to planarize a step difference caused by the transistor TR and to protect the transistor TR. The passivation layer 150 may include an organic film such as an acrylic resin, an epoxy resin, a phenolic resin, a polyamide resin, and/or a polyimide resin.

A light-emitting element layer EML including light-emitting elements LEL, photo-sensing pixels OPD, and a pixel defining layer 190 may be arranged on the passivation layer 150. Each of the light-emitting elements LEL includes a pixel electrode 171, a light-emitting layer 172, and a common electrode 173. Each of the photo-sensing pixels OPD includes a photo-sensing electrode PSE, a photo-sensing layer PSL, and a common electrode 173.

In detail, a pixel electrode layer may be arranged on the passivation layer 150. The pixel electrode layer includes a pixel electrode 171 and a photo-sensing electrode PSE. Each of the pixel electrode 171 and the photo-sensing electrode PSE may be connected to the connection electrode CE through a second contact hole CNT2 passing through the protective layer 150. In a top emission structure for emitting light in a direction of the common electrode 173 with respect to the light-emitting layer 172, the pixel electrode 171 may be formed as a single layer of molybdenum (Mo), titanium (Ti), copper (Cu), and/or aluminum (Al), or may be formed as a stacked structure (Ti/Al/Ti) of aluminum (Al) and titanium (Ti), a stacked structure (ITO/Al/ITO) of aluminum (Al) and indium tin oxide (ITO), APC alloy and a stacked structure (ITO/APC/ITO) of APC alloy and ITO. The APC alloy is an alloy of silver (Ag), palladium (Pd) and copper (Cu). The photo-sensing electrode PSE may be formed in the same manner as the pixel electrode 171.

The pixel defining layer 190 may be arranged on portions of the pixel electrode 171 and the photo-sensing electrode PSE and on the passivation layer 150. The pixel defining layer 190 serves to define the light-emitting areas EA1 to EA4 of the light-emitting pixels and the photo-sensing area RA of the sensing pixels. The pixel defining layer 190 may be formed to expose some areas of the pixel electrode 171 and the photo-sensing electrode PSE on the passivation layer 150. The pixel defining layer 190 may cover edges of the pixel electrode 171 and the photo-sensing electrode PSE. The pixel defining layer 190 may include an organic layer such as an acrylic resin, an epoxy resin, a phenolic resin, a polyamide resin, and/or a polyimide resin.

The light-emitting layer 172 may be arranged on the pixel electrode 171, and the photo-sensing layer PSL may be arranged on the photo-sensing electrode PSE. The light-emitting layer 172 may be an organic light-emitting layer containing an organic material. In this case, the light-emitting layer 172 may include a hole transporting layer, an organic light-emitting layer, and an electron transporting layer. When a voltage is applied to the pixel electrode through the thin film transistor TR of the thin film transistor layer TFTL, and a cathode voltage is applied to the common electrode 173, holes and electrons move to the organic light-emitting layer 172 through the hole transporting layer and the electron transporting layer, respectively, and may be combined with each other in the organic light-emitting layer to emit light. The pixels of the light-emitting element layer EML may be arranged in the display area DA.

The photo-sensing layer PSL may include an organic material. The photo-sensing layer PSL may generate light charges in proportion to incident light. In this case, the incident light may be light emitted from the light-emitting layer 172 and reflected, or may be light provided from the outside regardless of the light-emitting layer 172. The charges generated and accumulated in the photo-sensing layer PSL may be converted into electrical signals required for sensing.

The photo-sensing layer PSL may include an electron donating material and an electron receiving material. The electron donating material may generate donor ions in response to light, and the electron receiving material may generate acceptor ions in response to light. When the photo-sensing layer PSL includes an organic material, the electron donating material may include a compound such as subphthalocyanine (SubPc) and/or dibutylphosphate (DBP), but is not limited thereto. The electron receiving material may include a compound such as fullerene, a fullerene derivative, and/or perylene diimide, but is not limited thereto.

When the photo-sensing layer PSL includes an organic material, a hole injecting layer and a hole transporting layer may be arranged below the photo-sensing layer PSL, and an electron injecting layer and an electron transporting layer may be stacked above the photo-sensing layer PSL. Each of the hole injecting layer, the hole transporting layer, the electron injecting layer, and the electron transporting layer may be a single layer or multi-layer containing an organic material.

When the photo-sensing layer PSL includes an inorganic material, the photo-sensing pixel OPD may be a pn-type or a pn-type photo-transistor. For example, the photo-sensing layer PSL may have a structure in which an N-type semiconductor layer, an I-type semiconductor layer, and a P-type semiconductor layer are sequentially stacked.

The common electrode 173 may be arranged on the pixel defining layer 190, the light-emitting layer 172, and the photo-sensing layer PSL. The common electrode 173 may be formed to cover the light-emitting layer 172 and the photo-sensing layer PSL. The common electrode 173 may be a common layer commonly formed in the light-emitting areas EA1 to EA4 and the photo-sensing areas RA.

The encapsulation layer TFEL may be arranged on the light-emitting element layer EML. The encapsulation layer TFEL may include a first inorganic encapsulation layer TFE1 and a second inorganic encapsulation layer TFE3 to serve to prevent oxygen and/or moisture from being permeated into the light-emitting element layer EML. Each of the first inorganic encapsulation layer TFE1 and the second inorganic encapsulation layer TFE3 may be a silicon nitride layer, a silicon oxynitride layer, a silicon oxide layer, a titanium oxide layer, and/or an aluminum oxide layer, but is not limited thereto.

Also, the encapsulation layer TFEL may include an organic encapsulation layer TFE2 that serves to protect the light-emitting element layer EML from particles such as dust. The organic encapsulation layer TFE2 may be arranged between the first inorganic encapsulation layer TFE1 and the second inorganic encapsulation layer TFE3. The organic encapsulation layer TFE2 may be an acrylic resin, an epoxy resin, a phenolic resin, a polyamide resin, and/or a polyimide resin, but is not limited thereto.

The encapsulation layer TFEL may be arranged in both the display area DA and the non-display area NDA. In detail, in one or more embodiments, the encapsulation layer TFEL may be arranged to cover the light-emitting element layer EML of the display area DA and the non-display area NDA and cover the thin film transistor layer TFTL of the non-display area NDA.

The color filter layer CFL may be arranged on the encapsulation layer TFEL. The second color filter CF2 that transmits light of the second color is illustrated as being arranged in the second and fourth light-emitting areas EA2 and EA4 that emit light of the second color. The first color filter CF1 that transmits light of the first color may be arranged in the first light-emitting area EA1, and the third color filter CF3 that transmits light of the third color may be arranged in the third light-emitting area EA3. As a result, the light of the first color, which is emitted from the first light-emitting area EA1, may move to the outside of the display device 10 by passing through the first color filter CF1, and the light of the second color, which is emitted from the second light-emitting area EA2, may move to the outside of the display device 10 by passing through the second color filter CF2. The light of the third color, which is emitted from the third light-emitting area EA3, may move to the outside of the display device 10 by passing through the third color filter CF3, and the light of the second color, which is emitted from the fourth light-emitting area EA4, may move to the outside of the display device 10 by passing through the second color filter CF2.

The plurality of color filters may be arranged in the non-light-emitting area between the light-emitting areas EA1 to EA4 and the photo-sensing area RA. The non-light-emitting area may overlap the pixel defining layer 190 in the third direction (Z-axis direction). Although the third color filter CF3, the first color filter CF1, and the second color filter CF2 are illustrated as being sequentially stacked in the non-light-emitting area, the order in which the first to third color filters CF1 to CF3 are stacked may be modified. The plurality of color filters CF1 to CF3 may block light in the non-light-emitting area.

The first color filter CF1 may transmit the light of the first color (e.g., red light). The first color filter CF1 may transmit light included in a wavelength band of about 600 nm to about 750 nm.

The second color filter CF2 may transmit the light of the second color (e.g., green light). The second color filter CF2 may transmit light included in a wavelength band of about 500 nm to about 570 nm.

The third color filter CF3 may transmit the light of the third color (e.g., blue light). The third color filter CF3 may transmit light included in a wavelength band of approximately 430 nm to 490 nm.

A first planarization layer OC1 may be arranged on the color filters CF1 to CF3. The first planarization layer OC1 may planarize a step difference due to the color filters CF1 to CF3 of the color filter layer CFL. The first planarization layer OC1 may include an organic layer such as an acrylic resin, an epoxy resin, a phenolic resin, a polyamide resin, and/or a polyimide resin.

The first metalens ML1 may be arranged on the first planarization layer OC1. The first metalens ML1 may increase the amount of light received in the photo-sensing area RA by refracting light directed toward the photo-sensing area RA. The first metalens ML1 may overlap the photo-sensing area RA in the third direction (Z-axis direction). A width W_ML1 of the first metalens ML1 in the second direction (Y-axis direction) may be greater than a width of the photo-sensing area RA in the second direction (Y-axis direction). A portion of the first metalens ML1 may overlap the plurality of color filters CF1 to CF3 in the third direction (Z-axis direction).

The first metalens ML1 may include an inorganic material such as silicon nitride, silicon oxide, and/or titanium oxide, a metal material such as gold (Au) and/or silver (Ag), and/or an organic material such as an acrylic resin, an epoxy resin, a phenolic resin, a polyamide resin, and/or a polyimide resin. When the first metalens ML1 includes a metal material, a thickness of the metal material may be 200 nm or less to have transmittance. For example, a refractive index of the first metalens ML1 may range from 1.4 to 1.6, approximately.

An intermediate layer IOL may be arranged on the first planarization layer OC1 and the first metalens ML1. The intermediate layer IOL may include an inorganic layer, for example, a silicon nitride layer, a silicon oxynitride layer, a silicon oxide layer, a titanium oxide layer, and/or an aluminum oxide layer. The intermediate layer IOL may include a plurality of inorganic layers.

A black matrix BM may be arranged on the intermediate layer IOL. The black matrix BM may be formed using a material that absorbs visible light, for example, a metal material, a resin material containing a pigment and/or a dye, etc. The black matrix BM may block light of the light-emitting element LEL, thereby preventing color mixture between the pixels PX. The black matrix BM may overlap the pixel defining layer 190 in the third direction (Z-axis direction).

The black matrix BM may define a photo-sensing hole H_OPD that overlaps the photo-sensing area RA. A width of the photo-sensing hole H_OPD in the second direction (Y-axis direction) may be less than the width W_ML1 of the first metalens ML1 in the second direction (Y-axis direction). A portion of the black matrix BM may overlap an edge of the first metalens ML1 in the third direction (Z-axis direction).

A second planarization layer OC2 may be arranged on the black matrix BM and the intermediate layer IOL. The second planarization layer OC2 may planarize a step difference due to the black matrix BM. The second planarization layer OC2 may include an organic layer such as an acrylic resin, an epoxy resin, a phenolic resin, a polyamide resin, and/or a polyimide resin.

A window member WN may be arranged on the second planarization layer OC2. The window member WN may be attached onto the second planarization layer OC2 by a transparent adhesive member such as an optically clear adhesive (OCA) film and/or an optically clear resin (OCR). The window member WN may be an inorganic material such as glass or an organic material such as plastic or a polymer material.

The second metalens ML2 may be arranged on the window member WN. The second metalens ML2 may emit light totally reflected from the window member WN and trapped inside the display device 10 to the outside of the display device 10.

The second metalens ML2 may include a first sub-lens ML2_EA1 arranged in the first light-emitting area EA1, a second sub-lens ML2_EA2 arranged in the second light-emitting area EA2, a third sub-lens ML2_EA3 arranged in the third light-emitting area EA3, and a fourth sub-lens ML2_EA4 arranged in the fourth light-emitting area EA4.

A size of the first sub-lens ML2_EA1 may be greater than or equal to the size of the first light-emitting area EA1. The size of the second sub-lens ML2_EA2 may be greater than or equal to the size of the second light-emitting area EA2. A size of the third sub-lens ML2_EA3 may be greater than or equal to the size of the third light-emitting area EA3. A size of the fourth sub-lens ML2_EA4 may be greater than or equal to the size of the fourth light-emitting area EA4.

The second metalens ML2 may include an inorganic material such as silicon nitride, silicon oxide, titanium oxide, a metal material such as gold (Au) and/or silver (Ag), or an organic material such as an acrylic resin, an epoxy resin, a phenolic resin, a polyamide resin, and/or a polyimide resin. When the second metalens ML2 includes a metal material, a thickness of the metal material may be 200 nm or less to have transmittance. A refractive index of the second metalens ML2 may be similar to that of the window member WN. For example, the refractive index of the second metalens ML2 may be 1.4 to 1.6, approximately.

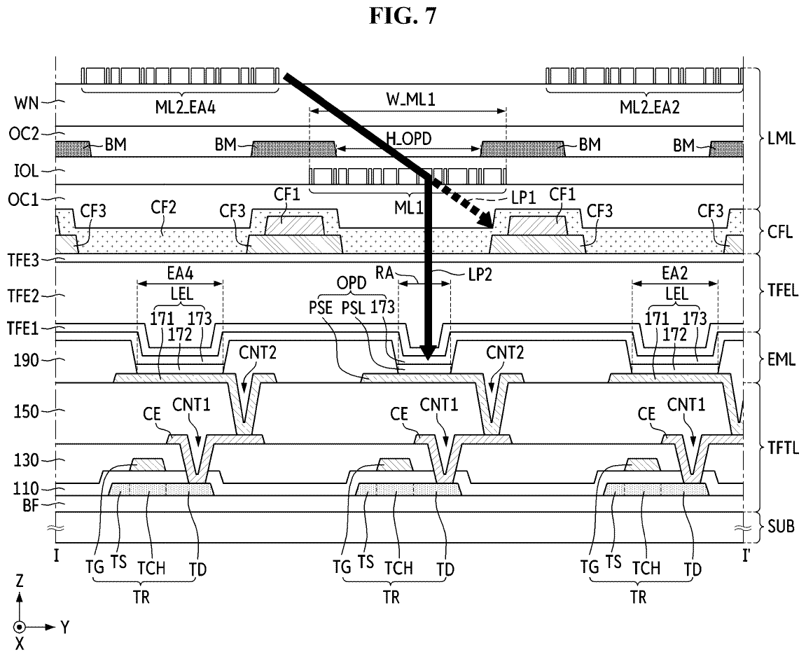

FIG. 7 is a cross-sectional view illustrating the photo-sensing area and the first metalens of FIG. 5. A redundant portion of the above description will be omitted or briefly described, and the following description will be based on differences from the above description.

Referring to FIG. 7, in the display device of the related art, some of light incident on the display device 10 from the outside moves to the non-light-emitting area. For example, in the display device of the related art, some of the light incident on the display device 10 from the outside moves toward the plurality of color filters CF1 to CF3 like a first light path LP1. Accordingly, even though the light has passed through the photo-sensing hole H_OPD, there is light that does not move to the photo-sensing area RA.

The display device 10 according to one or more embodiments of the present disclosure may include a first metalens ML1 arranged between the color filter layer CFL and the black matrix BM. Accordingly, light moving toward the plurality of color filters CF1 to CF3 may be refracted to the photo-sensing area RA like a second light path LP2. Accordingly, the display device 10 of the present disclosure may effectively increase the amount of light received in the photo-sensing area RA.

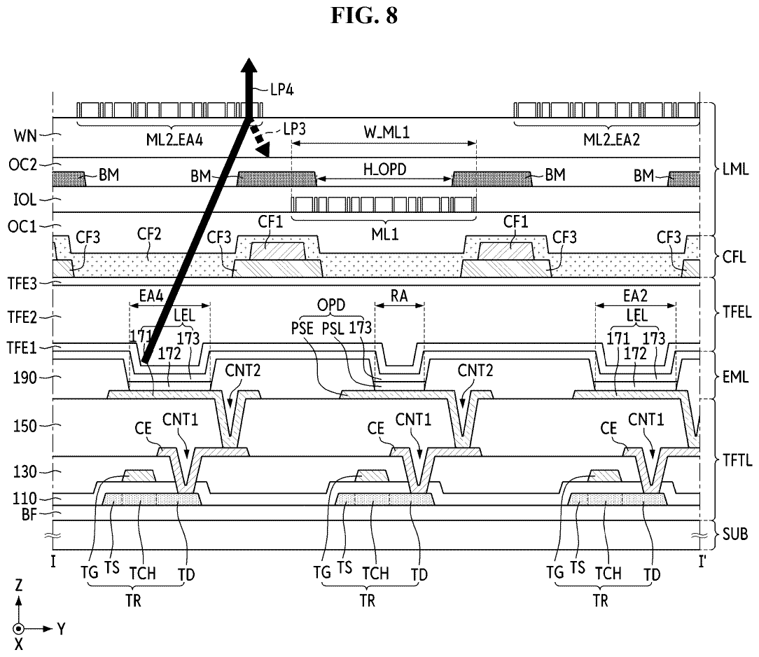

FIG. 8 is a cross-sectional view illustrating the light-emitting area and the second metalens of FIG. 5. A redundant portion of the above description will be omitted or briefly described, and the following description will be based on differences from the above description.

Referring to FIG. 8, in the display device of the related art, there is light that is totally reflected like a third light path LP3 without being emitted from the window member WN to the outside due to a difference in refractive index. For this reason, the light emitted from the light-emitting element LEL cannot be emitted to the outside of the display device, so the light emission efficiency may be lowered.

The display device 10 according to one or more embodiments of the present disclosure may include a second metalens ML2 arranged on the window member WN in the light-emitting areas EA1 to EA4. Because the refractive index of the second metalens ML2 is similar to that of the window member WN, the light, which is totally reflected from the window member WN to the inside of the display device 10, may be emitted to the outside of the display device 10 like a fourth light path LP4. Accordingly, the display device 10 of the present disclosure may effectively increase light emission efficiency of the light emitted from the light-emitting element LEL.

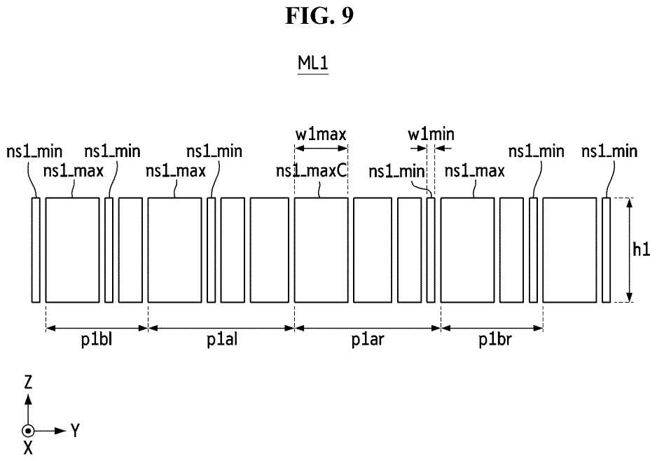

FIG. 9 is a cross-sectional view illustrating the first and second metalenses of FIG. 5.

In this drawing, the first metalens ML1 will be described as an example, but the first to fourth sub-lenses ML2_EA1 to ML2_EA4 of the second metalens ML2 may be also formed in the same manner.

Referring to FIG. 9, the first metalens ML1 may include a plurality of first nanostructures. The plurality of first nanostructures may have a first height, a first width, and a first period.

For convenience of description, the following description will be based on that the first heights of the plurality of first nanostructures are all the same as h1, but the present disclosure is not limited thereto, and the first height of each of the plurality of first nanostructures may be modified to have a specific pattern.

The first height h1 may be 1/10 times to 1 times a central wavelength of a second wavelength range transmitted by the second color filter CF2. This is to refract light that may transmit the second color filter CF2 toward the photo-sensing area RA through the first metalens ML1 because the first metalens ML1 overlaps the second color filter CF2 in the third direction (Z-axis direction).

As another example, when the first metalens ML1 overlaps the first color filter CF1 in the third direction (Z-axis direction), the first height h1 may be 1/10 times to 1 times a central wavelength of a first wavelength range transmitted by the first color filter CF1.

As another example, when the first metalens ML1 overlaps the third color filter CF3 in the third direction (Z-axis direction), the first height h1 may be 1/10 times to 1 times a central wavelength of a third wavelength range transmitted by the third color filter CF3.

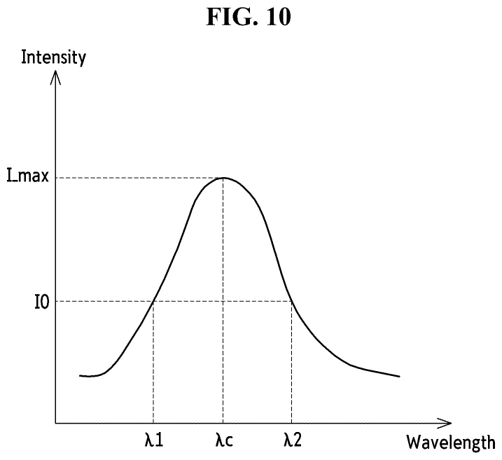

The wavelength range and the central wavelength will be described later with reference to FIG. 10.

The first width of each of the plurality of first nanostructures may be a first minimum width w1min or more and a first maximum width w1max or less. The first minimum width w1min may be 1/10 times the central wavelength of the second wavelength range transmitted by the second color filter CF2 overlapping the first metalens ML1 in the third direction (Z-axis direction). The first maximum width w1max may be 1 times the central wavelength of the second wavelength range.

A first central nanostructure ns1_maxC having a first maximum width w1max may be arranged at a center of the first metalens ML1. The plurality of first nanostructures may be arranged in a descending order from the first maximum width w1max to the first minimum width w1min in the second direction (Y-axis direction) with respect to the first central nanostructure ns1_maxC.

A first maximum nanostructure ns1_max having a first maximum width w1max may be arranged adjacent to a first minimum nanostructure ns1_min having a first minimum width w1min. A distance between the first central nanostructure ns1_maxC and the first maximum nanostructure ns1_max may be a first maximum period p1ar and p1al.

The plurality of first nanostructures may be repeatedly arranged in a descending order from the first maximum width w1max to the first minimum width w1min in the first direction (X-axis direction) and the second direction (Y-axis direction) with respect to the first maximum nanostructure ns1_max. In this case, a distance between the first maximum nanostructures ns1_max having a first maximum width w1max may be a first period. The first period may decrease from a central portion to an edge of the first metalens ML1. In detail, the number of first nanostructures included in the first period may decrease from the central portion to the edge of the first metalens ML1.

For example, the number of first nanostructures arranged within the first maximum period p1ar and p1al may be 4. The number of first nanostructures arranged within a first intermediate period p1br and p1bl adjacent to the first maximum period p1ar and p1al may be three. The first nanostructure arranged following the first intermediate period p1br and p1bl may include only two of the first maximum nanostructure ns1_max and the first minimum nanostructure ns1_min. In this way, the first period may decrease from the central portion to the edge of the first metalens ML1.

The second metalens ML2 may include first sub-structures arranged in the first light-emitting area EA1, second sub-structures arranged in the second light-emitting area EA2, third sub-structures arranged in the third light-emitting area EA3, and fourth sub-structures arranged in the fourth light-emitting area EA4. In this case, the fourth sub-structures may be formed to be substantially the same as the second sub-structures. Thus, the description of the fourth sub-structures will be omitted.

The first sub-structures may have a second height, a second width, and a second period. The second height of each of the first sub-structures may be 1/10 times to 1 times the central wavelength of the first wavelength range transmitted by the first color filter CF1. This is to effectively refract the light of the first color, which is transmitted by the first color filter CF1.

The second width of each of the first sub-structures may have a value of a second minimum width or more and a second maximum width or less. The second minimum width may be 1/10 times the central wavelength of the first wavelength range, and the second maximum width may be 1 times the central wavelength of the first wavelength range. The second period may decrease from a central portion to an edge of the first sub-lens ML2_EA1. The number of first sub-structures included in the second period may decrease from the central portion to the edge of the first sub-lens ML2_EA1.

The second sub-structures may have a third height, a third width, and a third period. The third height of each of the second sub-structures may be 1/10 to 1 times the central wavelength of the second wavelength range transmitted by the second color filter CF2. This is to effectively refract the light of the second color, which is transmitted by the second color filter CF2.

The third width of each of the second sub-structures may have a value of a third minimum width or more and a third maximum width or less. The third minimum width may be 1/10 times the central wavelength of the second wavelength range, and the third maximum width may be 1 times the central wavelength of the second wavelength range. The third period may decrease from a central portion to an edge of the second sub-lens ML2_EA2. The number of second sub-structures included in the third period may decrease from the central portion to the edge of the second sub-lens ML2_EA2.

The third sub-structures may have a fourth height, a fourth width, and a fourth period. The fourth height of each of the third sub-structures may be 1/10 times to 1 times the central wavelength of the third wavelength range transmitted by the third color filter CF3. This is to effectively refract light of the third color, which is transmitted by the third color filter CF3.

The fourth width of each of the third sub-structures may have a value of a fourth minimum width or more and a fourth maximum width or less. The fourth minimum width may be 1/10 times the central wavelength of the third wavelength range, and the fourth maximum width may be 1 times the central wavelength of the third wavelength range. The fourth period may decrease from a central portion to an edge of the third sub-lens ML2_EA3. The number of third sub-structures included in the fourth period may decrease from the central portion to the edge of the third sub-lens ML2_EA3. The fourth sub-structures may be formed substantially the same as the second sub-structures. Thus, the description of the fourth sub-structures will be omitted.

FIG. 10 is a graph illustrating a relationship between the wavelength of light transmitted though the color filter of FIG. 5 vs. intensity of light, according to one or more embodiments.

Referring to FIG. 10, each of the color filters CF1 to CF3 may have a different transmittance depending on wavelengths. Each of the color filters CF1 to CF3 may have a maximum transmittance with respect to a central wavelength λc. That is, each of the color filters CF1 to CF3 may have a maximum intensity I_max at the central wavelength λc. In this case, the central wavelength λc may be included in a wavelength band of a first wavelength λ1 to a second wavelength λ2. The first wavelength λ1 and the second wavelength λ2 may have wavelengths in which intensity of transmitted light is a reference intensity I0 with respect to each of the color filters CF1 to CF3.

For example, in case of the first color filter CF1 that transmits red light, the first wavelength λ1 may be about 600 nm, and the second wavelength λ2 may be about 750 nm. The central wavelength λc of the first color filter CF1 may be any value between the first wavelength λ1 and the second wavelength λ2. For example, the central wavelength λc of the first color filter CF1 may be 675 nm, which is an average value of the first wavelength λ1 and the second wavelength λ2, but the present disclosure is not limited thereto.

In case of the second color filter CF2 that transmits green light, the first wavelength λ1 may be about 500 nm, and the second wavelength λ2 may be about 570 nm. The central wavelength λc of the second color filter CF2 may be any value between the first wavelength λ1 and the second wavelength λ2. For example, the central wavelength λc of the second color filter CF2 may be 535 nm, which is an average value of the first wavelength λ1 and the second wavelength λ2, but the present disclosure is not limited thereto.

In case of the third color filter CF3 that transmits blue light, the first wavelength λ1 may be about 430 nm, and the second wavelength λ2 may be about 490 nm. The central wavelength λc of the third color filter CF3 may be any value between the first wavelength λ1 and the second wavelength λ2. For example, the central wavelength λc of the third color filter CF3 may be 460 nm, which is an average value of the first wavelength λ1 and the second wavelength λ2, but the present disclosure is not limited thereto.

Referring back to FIG. 9, the first height h1 of the plurality of first nanostructures may have any value between 500 nm, which is the first wavelength λ1, and 570 nm, which is the second wavelength λ2, with respect to the second color filter CF2. The first width of the plurality of first nanostructures may be in the range of 53.5 nm to 535 nm, which is 1/10 times to 1 times 535 nm that is the central wavelength λc of the second color filter CF2.

The second height of the first sub-structures may have any value between 600 nm, which is the first wavelength λ1, and 750 nm, which is the second wavelength λ2, with respect to the first color filter CF1. The second width of the first sub-structures may be in the range of 67.5 nm to 675 nm, which is 1/10 times to 1 times 675 nm that is the central wavelength λc of the first color filter CF1.

The third height of the second sub-structures may have any value between 500 nm, which is the first wavelength λ1, and 570 nm, which is the second wavelength λ2, with respect to the second color filter CF2. The third width of the second sub-structures may be in the range of 53.5 nm to 535 nm, which is 1/10 times to 1 times 535 nm that is the central wavelength λc with respect to the second color filter CF2.

The fourth height of the third sub-structures may have any value between 430 nm, which is the first wavelength λ1, and 490 nm, which is the second wavelength λ2, with respect to the third color filter CF3. The fourth width of the third sub-structures may be in the range of 46 nm to 460 nm, which is 1/10 times to 1 times 460 nm that is the central wavelength λc with respect to the third color filter CF3.

The fourth sub-structures may be formed substantially the same as the second sub-structures. Thus, the description of the fourth sub-structures will be omitted.

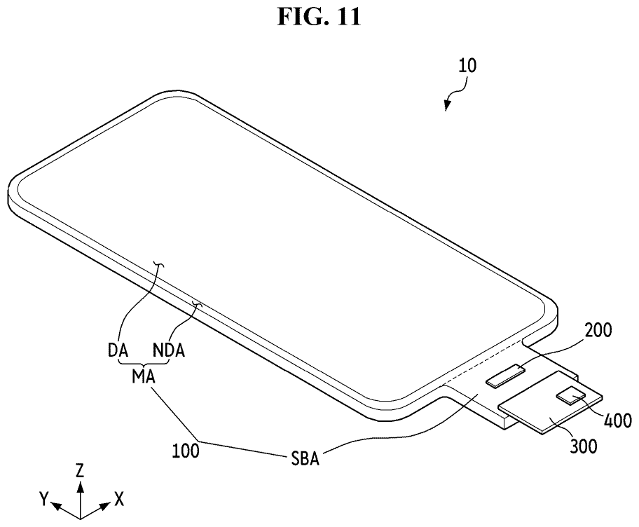

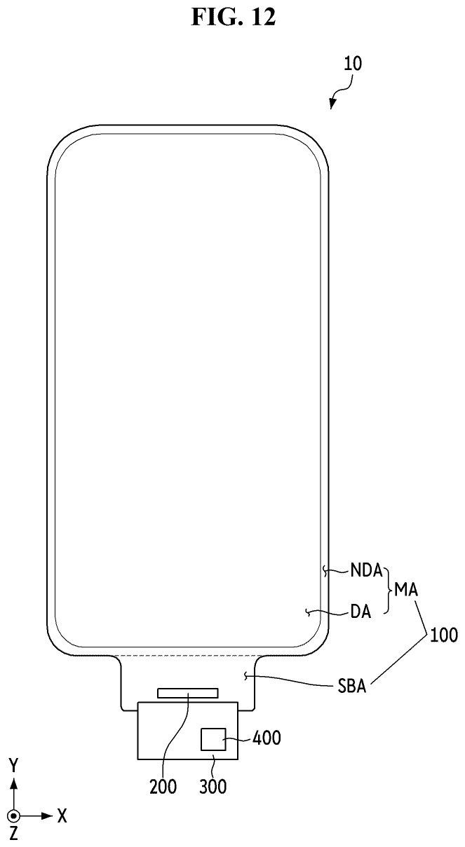

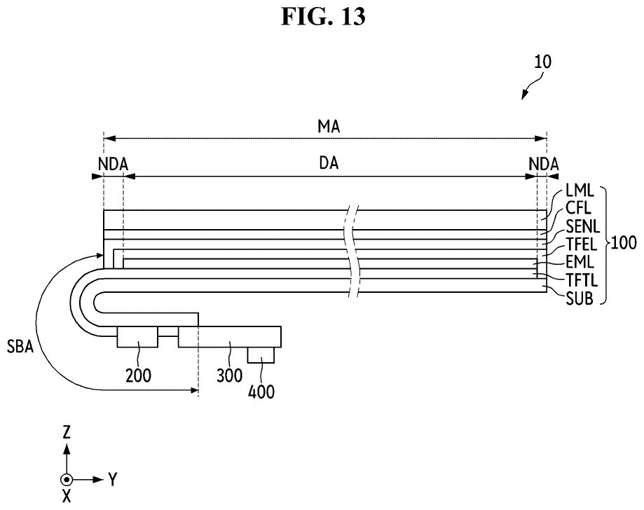

FIG. 11 is a perspective view illustrating a display device according to one or more embodiments of the present disclosure. FIG. 12 is a plan view illustrating an example of the display device of FIG. 11. FIG. 13 is a side view illustrating another example of the display device of FIG. 11. A redundant portion of the above description will be omitted or briefly described, and the following description will be based on differences from the above description.

Referring to FIGS. 11 and 12, the display device 10 according to one or more embodiments of the present disclosure includes a display panel 100, a display driving circuit 200, a display circuit board 300, and a touch driving circuit 400.

Compared with FIGS. 1 and 2, the display device 10 may further include a touch driving circuit 400.

The touch driving circuit 400 may be arranged on the display circuit board 300. The touch driving circuit 400 may be formed as an integrated circuit (IC) and attached onto the display circuit board 300.

Referring to FIG. 13, the display panel 100 may include a substrate SUB, a thin film transistor layer TFTL, a light-emitting element layer EML, an encapsulation layer TFEL, a touch sensing layer SENL, a color filter layer CFL, and a light modulation layer LML.

Compared with FIG. 3, the display panel 100 may further include a touch sensing layer SENL arranged between the encapsulation layer TFEL and the color filter layer CFL.

The touch driving circuit 400 may be electrically connected to the sensor electrodes of the touch sensing layer SENL of the display panel 100. The touch driving circuit 400 applies driving signals to the sensor electrodes of the touch sensing layer SENL and measures mutual capacitance values of the sensor electrodes. The driving signal may be a signal having a plurality of driving pulses. The touch driving circuit 400 may determine whether there is a user's touch or a user's proximity, depending on the mutual capacitance values. The user's touch means that an object such as a user's finger or pen directly contacts one surface of the display device 10, which is arranged on the touch sensing layer SENL. The user's proximity means that an object such as a user's finger or pen is positioned spaced (e.g., spaced apart) from one surface of the display device 10 (hovering).

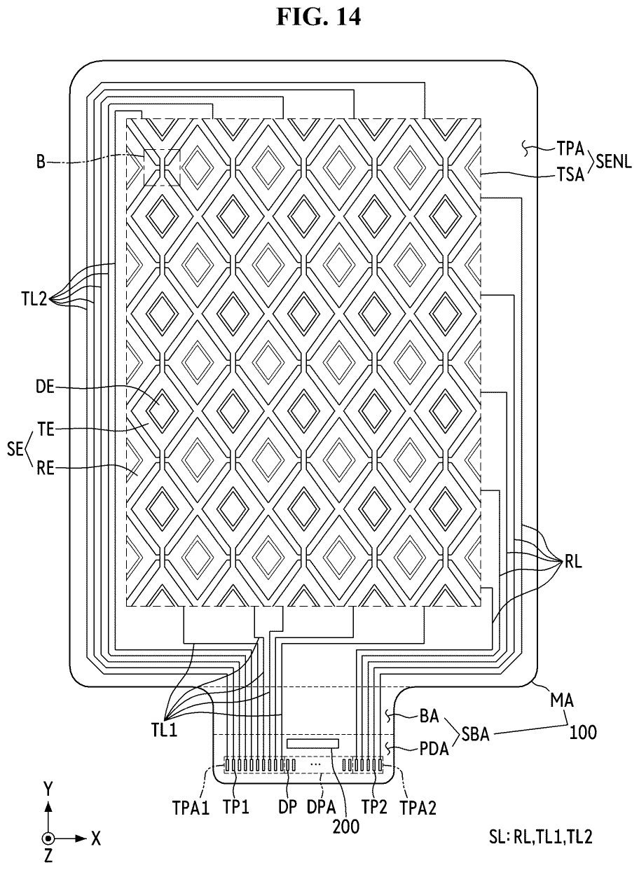

FIG. 14 is a layout view illustrating the touch sensing layer of FIG. 13.

In FIG. 14, the sensor electrodes SE of the touch sensing layer SENL include two types of electrodes, for example, driving electrodes TE and sensing electrodes RE, and are described as being driven in a mutual capacitance manner in which a voltage charged in mutual capacitance is sensed through the sensing electrodes RE after a driving signal is applied to the driving electrodes TE, but are not limited thereto.

For convenience of description, driving electrodes TE, sensing electrodes RE, dummy patterns DE, sensor lines TL1, TL2, and RL, and sensor pads TP1 and TP2 are only shown in FIG. 14.

Referring to FIG. 14, the touch sensing layer SENL includes a touch sensor area TSA for sensing a user's touch and a touch peripheral area TPA arranged around the touch sensor area TSA. The touch sensor area TSA may overlap the display area DA of FIG. 11-13, and the touch peripheral area TPA may overlap the non-display area NDA of FIG. 11-13.

The touch sensor area TSA includes driving electrodes TE, sensing electrodes RE, and dummy patterns DE. The driving electrodes TE and the sensing electrodes RE may be electrodes for forming mutual capacitance to sense a touch of an object or a person.

The sensing electrodes RE may be arranged in parallel in the first direction (X-axis direction) and the second direction (Y-axis direction). The sensing electrodes RE may be electrically connected to each other in the first direction (X-axis direction). The sensing electrodes RE adjacent to each other in the first direction (X-axis direction) may be connected to each other. The sensing electrodes RE adjacent to each other in the second direction (Y-axis direction) may be electrically separated from each other.

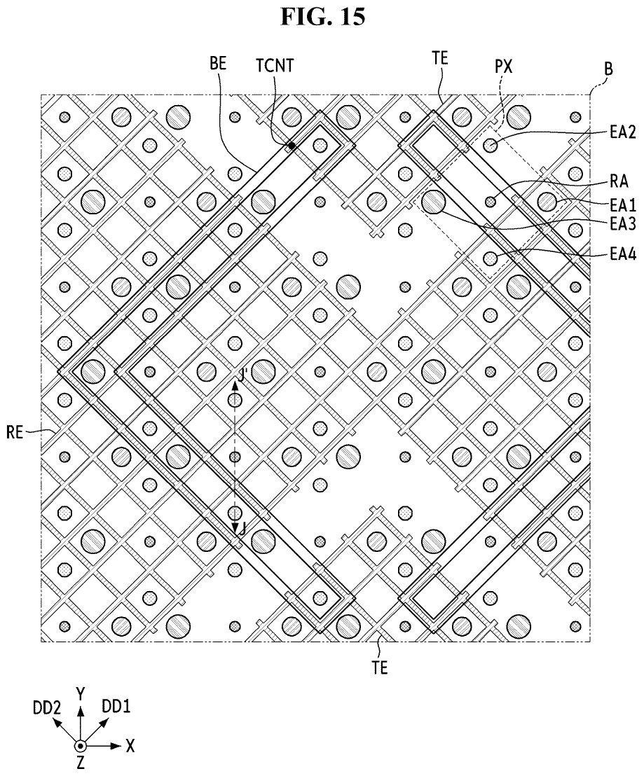

The driving electrodes TE may be arranged in parallel in the first direction (X-axis direction) and the second direction (Y-axis direction). The driving electrodes TE adjacent to each other in the first direction (X-axis direction) may be electrically separated from each other. The driving electrodes TE may be electrically connected to each other in the second direction (Y-axis direction). For example, the driving electrodes TE adjacent to each other in the second direction (Y-axis direction) may be connected to each other through the connection electrode BE as shown in FIG. 15.

Each of the dummy patterns DE may be surrounded by the driving electrode TE or the sensing electrode RE. Each of the dummy patterns DE may be electrically separated from the driving electrode TE or the sensing electrode RE. Each of the dummy patterns DE may be arranged to be spaced (e.g., spaced apart) from the driving electrode TE or the sensing electrode RE. Each of the dummy patterns DE may be electrically floated.

Each of the driving electrodes TE, the sensing electrodes RE, and the dummy pattern DE is illustrated in FIG. 14 as having a rhombus planar shape, but is not limited thereto. For example, each of the driving electrodes TE, the sensing electrodes RE, and the dummy pattern DE may have a planar shape of a rectangular shape other than the rhombus shape, a polygonal shape other than the rectangular shape, a circular shape or an oval shape.

The sensor lines TL1, TL2, and RL may be arranged in the sensor peripheral area TPA. The sensor lines TL1, TL2, and RL include sensing lines RL connected to the sensing electrodes RE, and first and second driving lines TL1 and TL2 connected to the driving electrodes TE.

The sensing electrodes RE arranged on one side of the touch sensor area TSA may be connected to the sensing lines RL on a one-to-one basis. For example, as shown in FIG. 14, among the sensing electrodes RE electrically connected in the first direction (X-axis direction), the sensing electrode RE arranged at the right end may be connected to the sensing lines RL. The sensing lines RL may be connected to the second sensor pads TP2 on a one-to-one basis. Therefore, the touch driving circuit 400 may be electrically connected to the sensing electrodes RE.

The driving electrodes TE arranged on one side of the touch sensor area TSA may be connected to the first driving lines TL1 on a one-to-one basis, and the driving electrodes TE arranged on the other side of the touch sensor area TSA may be connected to the second driving lines TL2 on a one-to-one basis. For example, as shown in FIG. 14, among the driving electrodes TE electrically connected in the second direction (Y-axis direction), the driving electrode TE arranged at the lower end may be connected to the first driving line TL1, and the driving electrode TE arranged at the upper end may be connected to the second driving line TL2. The second driving lines TL2 may be connected to the driving electrodes TE at the upper side of the touch sensor area TSA through the left outer side of the touch sensor area TSA.

The first driving lines TL1 and the second driving lines TL2 may be connected to the first sensor pads TP1 on a one-to-one basis. Therefore, the touch driving circuit 400 may be electrically connected to the driving electrodes TE. Because the driving electrodes TE are connected to the driving lines TL1 and TL2 on respective sides of the touch sensor area TSA to receive a touch driving signal, a difference between a touch driving signal applied to the driving electrodes TE arranged below the touch sensor area TSA and a touch driving signal applied to the driving electrodes TE arranged above the touch sensor area TSA may be avoided due to RC delay of the touch driving signal.

The first sensor pad area TPA1 in which the first sensor pads TP1 are arranged may be arranged on one side of the display pad area DPA in which the display pads DP are arranged. The second sensor pad area TPA2 in which the second sensor pads TP2 are arranged may be arranged on the other side of the display pad area DPA. The display pads DP may be electrically connected to data lines of the display panel 100.

The display pad area DPA, the first sensor pad area TPA1, and the second sensor pad area TPA2 may correspond to pads of the display panel 100 connected to the display circuit board 300 shown in FIG. 12. The display circuit board 300 may be arranged on the display pads DP, the first sensor pads TP1, and the second sensor pads TP2. The display pads DP, the first sensor pads TP1, and the second sensor pads TP2 may be electrically connected to the display circuit board 300 by using a low resistance high reliability material such as an anisotropic conductive film or SAP. Therefore, the display pads DP, the first sensor pads TP1, and the second sensor pads TP2 may be electrically connected to the touch driving circuit 400 arranged on the display circuit board 300.

FIG. 15 is an enlarged layout view illustrating an area B of FIG. 14. A redundant portion of the above description will be omitted or briefly described, and the following description will be based on differences from the above description.

Referring to FIG. 15, the driving electrodes TE and the sensing electrodes RE are arranged on (e.g., at) the same layer and thus may be spaced (e.g., spaced apart) from each other. A gap may be formed between the driving electrode TE and the sensing electrode RE, which are adjacent to each other.

In addition, the dummy pattern DE may also be arranged on (e.g., at) the same layer as the driving electrodes TE and the sensing electrodes RE. That is, a gap may be formed between the driving electrode TE and the dummy pattern DE, which are adjacent to each other, and between the sensing electrodes RE and the dummy pattern DE, which are adjacent to each other.

The connection electrodes BE may be arranged on a different layer from the driving electrodes TE and the sensing electrodes RE. The connection electrode BE may be bent at least once. Although the connection electrode BE is illustrated in FIG. 15 as having a clamp shape such as “<” or “>”, a planar shape of the connection electrode BE is not limited thereto. Because the driving electrodes TE adjacent to each other in the second direction (Y-axis direction) are connected to each other by the plurality of connection electrodes BE, even though any one of the connection electrodes BE is disconnected, the driving electrodes TE adjacent to each other in the second direction (Y-axis direction) may be stably connected to each other. The driving electrodes TE adjacent to each other are illustrated in FIG. 15 as being connected by two connection electrodes BE, but the number of the connection electrodes BE is not limited thereto.

The connection electrode BE may overlap the driving electrodes TE, which are adjacent to each other in the second direction (Y-axis direction), in the third direction (Z-axis direction) that is a thickness direction of the substrate SUB. The connection electrode BE may overlap the sensing electrode RE in the third direction (Z-axis direction). One side of the connection electrode BE may be connected to one of the driving electrodes TE adjacent to each other in the second direction (Y-axis direction) through touch contact holes TCNT. The other side of the connection electrode BE may be connected to the other driving electrode TE among the driving electrodes TE, which are adjacent to each other in the second direction (Y-axis direction), through the touch contact holes TCNT.

Due to the connection electrodes BE, the driving electrodes TE and the sensing electrodes RE may be electrically separated from each other at their intersections. For this reason, mutual capacitance may be formed between the driving electrodes TE and the sensing electrodes RE.

Each of the driving electrodes TE, the sensing electrodes RE, and the connection electrodes BE may have a planar shape of a mesh structure or a net structure. Also, each of the dummy patterns DE may have a planar shape of a mesh structure or a net structure. Accordingly, each of the driving electrodes TE, the sensing electrodes RE, the connection electrodes BE, and the dummy pattern DE may be arranged to be spaced (e.g., spaced apart) from the light-emitting areas EA1 to EA4 of each of the pixels PX and the photo-sensing area RA of the photo-sensing pixel OPD. As a result, light emitted from the light-emitting areas EA1 to EA4 is covered by the driving electrodes TE, the sensing electrodes RE, the connection electrodes BE, and the dummy pattern DE, whereby luminance of light may be prevented from being reduced. Also, the light incident on the photo-sensing area RA is covered by the driving electrodes TE, the sensing electrodes RE, the connection electrodes BE, and the dummy patterns DE, whereby the amount of light received in the photo-sensing area RA may be prevented from being reduced.

FIG. 16 is a cross-sectional view taken along the line J-J′ of FIG. 15. A redundant portion of the above description will be omitted or briefly described, and the following description will be based on differences from the above description.

Referring to FIG. 16, the display panel 100 may include a substrate SUB, a thin film transistor layer TFTL, a light-emitting element layer EML, an encapsulation layer TFEL, a touch sensing layer SENL, a color filter layer CFL, and a light modulation layer LML.

Compared with FIG. 6, the display panel 100 may further include a touch sensing layer SENL arranged between the encapsulation layer TFEL and the color filter layer CFL.

The touch sensing layer SENL may include a first touch insulating layer TINS1, a second touch insulating layer TINS2, a third touch insulating layer TINS3, a driving electrode TE, a sensing electrode RE, and a connection electrode BE.

The first touch insulating layer TINS1 may be arranged on the encapsulation layer TFEL. The first touch insulating layer TINS1 is an inorganic layer, and may be a silicon nitride layer, a silicon oxynitride layer, a silicon oxide layer, a titanium oxide layer, and/or an aluminum oxide layer, but is not limited thereto.

The connection electrode BE may be arranged on the first touch insulating layer TINS1. The connection electrode BE may be formed as a single layer or multi-layer made of molybdenum (Mo), aluminum (Al), chromium (Cr), gold (Au), titanium (Ti), nickel (Ni), neodymium (Nd), and/or copper (Cu), and/or their alloy. The connection electrode BE may overlap the pixel defining layer 190, the plurality of color filters CF1 to CF3, and the black matrix BM in the third direction (Z-axis direction). The connection electrode BE may be covered by the plurality of color filters CF1 to CF3 and the black matrix BM, and thus may not be visually recognized by the user.

The second touch insulating layer TINS2 may be arranged on the connection electrode BE and on the first touch insulating layer TINS1. The second touch insulating layer TINS2 may be formed as an inorganic layer, for example, a silicon nitride layer, a silicon oxynitride layer, a silicon oxide layer, a titanium oxide layer, and/or an aluminum oxide layer.

The driving electrode TE and the sensing electrode RE may be arranged on the second touch insulating layer TINS2. Also, the dummy patterns DE, the first driving lines TL1, the second driving lines TL2, and the sensing lines RL, which are shown in FIG. 14, may be arranged on the second touch insulating layer TINS2.

The driving electrode TE and the sensing electrode RE may overlap the connection electrode BE in the third direction (Z-axis direction). The driving electrode TE may be connected to the connection electrode BE through a touch contact hole TCNT passing through the second touch insulating layer TINS2. The driving electrode TE and the sensing electrode RE may overlap the pixel defining layer 190, the plurality of color filters CF1 to CF3, and the black matrix BM. The driving electrode TE and the sensing electrode RE may be covered by the plurality of color filters CF1 to CF3 and the black matrix BM, and thus may not be visually recognized by the user.

The third touch insulating layer TINS3 may be arranged on the driving electrode TE and the sensing electrode RE and on the second touch insulating layer TINS2. The third touch insulating layer TINS3 may be formed as an inorganic layer, for example, a silicon nitride layer, a silicon oxynitride layer, a silicon oxide layer, a titanium oxide layer, and/or an aluminum oxide layer.

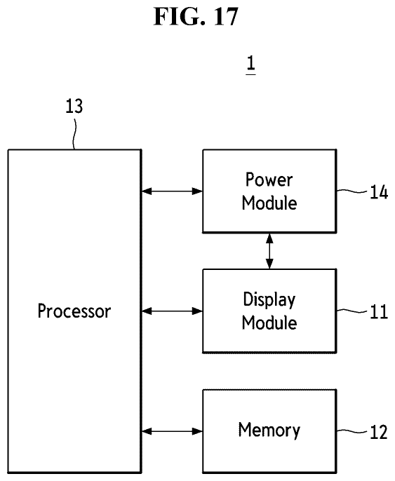

FIG. 17 is a block diagram illustrating an electronic device including a display device according to one or more embodiments of the present disclosure.

Referring to FIG. 17, an electronic device 1 according to one or more embodiments may include a display module 11, a processor 13, a memory 12, and a power module 14.

The processor 13 may include at least one of a central processing unit (CPU), an application processor (AP), a graphic processing unit (GPU), a communication processor (CP), an image signal processor (ISP), and/or a controller.

Data information required for an operation of the processor 13 or the display module 11 may be stored in the memory 12. When the processor 12 executes an application stored in the memory 12, an image data signal and/or an input control signal is transmitted to the display module 11, and the display module 11 may process the received signal and output image information through a display screen.

The power module 14 may include a power supply module such as a power adapter or a battery device, and a power conversion module that converts a power source supplied by the power supply module to generate a power source required for the operation of the electronic device 1.

At least one of the respective components of the above-described electronic device 1 may be included in the display device according to the above-described embodiments. Also, some of the individual modules functionally included in one module may be included in the display device, and others thereof may be provided separately from the display device. For example, the display device includes the display module 11, and the processor 13, the memory 12 and the power module 14 may be provided as other devices in the electronic device 1 not the display device.

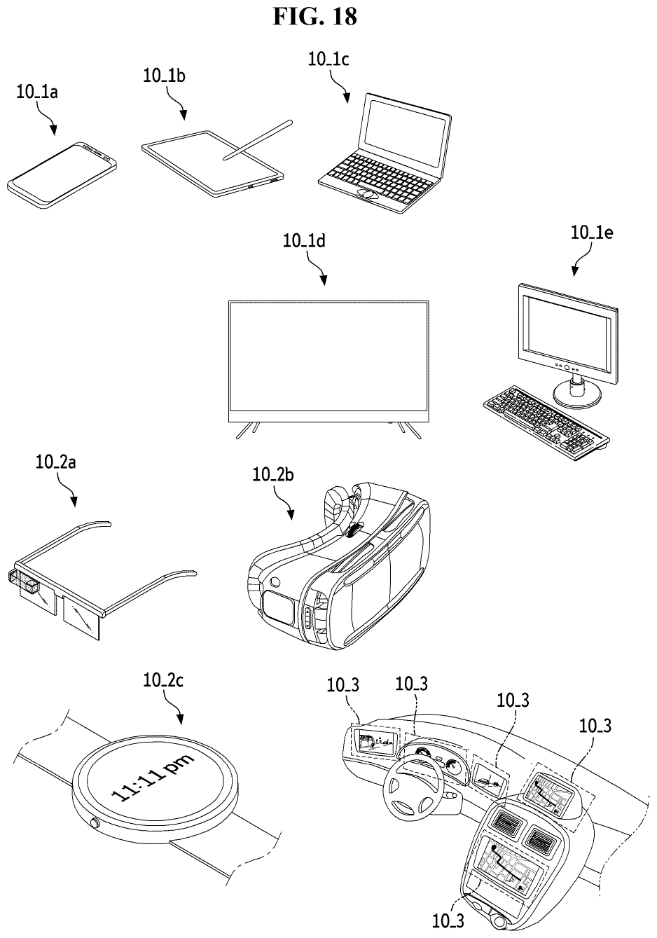

FIG. 18 is a view illustrating an electronic device comprising a display device including an optical filter according to some embodiments.

Referring to FIG. 18, various electronic devices to which the display devices according to the embodiments are applied may include not only electronic devices for image display, such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and a vehicle electronic device 10_3 including display modules such as a vehicle dashboard, a center fascia, a center information display (CID) arranged on the dashboard, and a room mirror display.

It will be understood by one of ordinary skill in the art to which the present disclosure belongs that the present disclosure may be implemented in one or more suitable forms without changing the spirit and scope of the present disclosure. Therefore, it will be understood that the one or more embodiments as described in the present disclosure are illustrative rather than being restrictive in all aspects. It will be understood that the scope of the present disclosure are defined by the scope of the appended claims and equivalents thereof rather than the detailed description as described above and all modifications and alterations derived from the appended claims and their equivalents fall within the scope of the present disclosure.

What is claimed is:

1. A display device comprising
a substrate;
a plurality of light-emitting pixel electrodes on one side of the substrate;
a plurality of sensing pixel electrodes on one surface of the substrate and spaced from the plurality of light-emitting pixel electrodes;
a pixel defining layer exposing a portion of each of the plurality of light-emitting pixel electrodes and the plurality of sensing pixel electrodes and defining a plurality of light-emitting areas and a plurality of photo-sensing areas;
a plurality of light-emitting layers on the plurality of light-emitting pixel electrodes in the plurality of light-emitting areas;
a plurality of photo-sensing layers on the plurality of sensing pixel electrodes in the plurality of photo-sensing areas, the plurality of photo-sensing layers configured to sense light reflected from a user;
a common electrode on the pixel defining layer, the plurality of light-emitting layers, and the plurality of photo-sensing layers;
an encapsulation layer on the common electrode, the encapsulation layer comprising at least one organic layer and at least one inorganic layer;
a first metalens on the encapsulation layer, the first metalens comprising a plurality of first nanostructures overlapping the plurality of photo-sensing areas in a thickness direction of the substrate;
an intermediate layer on the plurality of first nanostructures;
a black matrix in a non-light-emitting area between the plurality of light-emitting areas and the plurality of photo-sensing areas on the intermediate layer;
a window member on the black matrix and the intermediate layer; and
a second metalens on the window member, the second metalens comprising a plurality of second nanostructures overlapping the plurality of light-emitting areas in the thickness direction of the substrate.

2. The display device of claim 1, wherein the plurality of first nanostructures have a first height, a first width, and a first period.

3. The display device of claim 2, wherein the respective first heights of the plurality of first nanostructures are the same as each other.

4. The display device of claim 2, further comprising a first color filter in the plurality of photo-sensing areas on the encapsulation layer,
wherein the first height of each of the plurality of first nanostructures is from 1/10 to 1 times a central wavelength of a first wavelength range transmitted by the first color filter, and
wherein the central wavelength is defined as a wavelength of light having the largest intensity from among light passing through the first color filter.

5. The display device of claim 2, wherein the first width of each of the plurality of first nanostructures has a value of a first minimum width or more, and a first maximum width or less.

6. The display device of claim 5, wherein a first nanostructure of the plurality of first nanostructures having the first maximum width from among the plurality of first nanostructures is arranged at a central portion of the first metalens.

7. The display device of claim 5, wherein the plurality of first nanostructures are arranged in a descending order from the first maximum width to the first minimum width within the first period.

8. The display device of claim 7, wherein the first period is a distance between the first nanostructures having the first maximum width from among the plurality of first nanostructures.

9. The display device of claim 8, wherein the first period decreases from a central portion to an edge of the first metalens.

10. The display device of claim 1, wherein a width of the first metalens in a first direction is greater than a width of each of the plurality of photo-sensing areas in the first direction.

11. The display device of claim 1, wherein the plurality of second nanostructures comprises:
first sub-structures arranged in a first light-emitting area configured to emit light of a first color from among the plurality of light-emitting areas;
second sub-structures arranged in a second light-emitting area configured to emit light of a second color from among the plurality of light-emitting areas; and
third sub-structures arranged in a third light-emitting area configured to emit light of a third color from among the plurality of light-emitting areas.

12. The display device of claim 11, wherein the first sub-structures have a second height, a second width, and a second period.

13. The display device of claim 12, further comprising a first color filter in the first light-emitting area on the encapsulation layer,
wherein the second height of each of the first sub-structures is from 1/10 to 1 times a central wavelength of a first wavelength range transmitted by the first color filter.

14. The display device of claim 12, wherein the second sub-structures have a third height, a third width, and a third period, and
wherein the first sub-structures are different from the second sub-structures.

15. The display device of claim 14, further comprising a second color filter in the second light-emitting area on the encapsulation layer,
wherein the third height of each of the second sub-structures is from 1/10 to 1 times a central wavelength of a second wavelength range transmitted by the second color filter.

16. The display device of claim 14, wherein the third sub-structures have a fourth height, a fourth width, and a fourth period, and
wherein the third sub-structures are different from the first sub-structures and the second sub-structures.

17. The display device of claim 16, further comprising a third color filter arranged in the third light-emitting area on the encapsulation layer,
wherein the fourth height of each of the third sub-structures is from 1/10 to 1 times a central wavelength of a third wavelength range transmitted by the third color filter.

18. The display device of claim 11, wherein a width of the second metalens comprising the first sub-structures in the thickness direction of the substrate is greater than a width of the first light-emitting area in the thickness direction of the substrate.

19. The display device of claim 1, further comprising:
a plurality of inorganic insulating films on the encapsulation layer; and
touch electrodes between the plurality of inorganic insulating films, forming mutual capacitance.

20. An electronic device comprising a display device, the display device comprising:
a substrate;
a plurality of light-emitting pixel electrodes on one side of the substrate;
a plurality of sensing pixel electrodes on one surface of the substrate and spaced from the plurality of light-emitting pixel electrodes;
a pixel defining layer exposing a portion of each of the plurality of light-emitting pixel electrodes and the plurality of sensing pixel electrodes and defining a plurality of light-emitting areas and a plurality of photo-sensing areas;
a plurality of light-emitting layers on the plurality of light-emitting pixel electrodes in the plurality of light-emitting areas;
a plurality of photo-sensing layers on the plurality of sensing pixel electrodes in the plurality of photo-sensing areas, the plurality of photo-sensing layers configured to sense light reflected to a user;
a common electrode on the pixel defining layer, the plurality of light-emitting layers, and the plurality of photo-sensing layers;
an encapsulation layer on the common electrode, the encapsulation layer comprising at least one organic layer and at least one inorganic layer;
a first metalens on the encapsulation layer, the first metalens comprising a plurality of first nanostructures overlapping the plurality of photo-sensing areas in a thickness direction of the substrate;
an intermediate layer on the plurality of first nanostructures;
a black matrix in a non-light-emitting area between the plurality of light-emitting areas and the plurality of photo-sensing areas on the intermediate layer;
a window member on the black matrix and the intermediate layer; and
a second metalens on the window member, the second metalens comprising a plurality of second nanostructures overlapping the plurality of light-emitting areas in the thickness direction of the substrate.
